(19) United States
(12) Patent Application Publication
(10) Pub. No.: US 2026/0243646 A1
(43) Pub. Date: Aug. 20, 2026

(54) MAGNETIC RHEOMETRY METHOD

(71) Applicant: Aalto University Foundation sr, Aalto (FI)

(72) Inventors: Ossi Arasalo, Aalto (FI); Arttu Lehtonen, Aalto (FI); Juho Pokki-Riikonen, Aalto (FI); Linda Srbova, Aalto (FI)

(21) Appl. No.: 19/159,422

(22) PCT Filed: Feb. 29, 2024
(86) PCT No.: PCT/FI2024/050078

§ 371 Date: Aug. 25, 2025

(30) Foreign Application Priority Data
Mar. 1, 2023 (FI) 20237041

(51) Int. Cl. G01N 11/16; G01N 11/00; G01R 33/12; G06T 7/73; H01F 1/44

(52) U.S. Cl. CPC G01N 11/16; G01R 33/1276; G06T 7/74; H01F 1/447; G01N 2011/0006; G01N 2011/0086; G06T 2207/10016

(57) ABSTRACT

According to an example aspect of the present invention, there is provided a magnetic microrheometry method for estimating microscale viscoelasticity, the method comprising obtaining a 3D culture matrix comprising magnetic spheres, said magnetic spheres having a sphere diameter, exerting a sinusoidally varying magnetic force using a microrheometer thereby causing sinusoidally varying displacement of the magnetic spheres in the 3D culture matrix, measuring the displacement of said magnetic spheres, and estimating microscale viscoelasticity heterogeneity within the 3D culture matrix based at least on the exerted magnetic force and the measured displacement of said magnetic spheres.

### FIELD

The invention relates to 3D cell culture viscoelasticity characterization.

### BACKGROUND

The progression of breast cancer involves cancer-cell invasions of extracellular matrices. To investigate the progression, 3D cell cultures are widely used along with different types of matrices. Currently, the matrices are often characterized using parallel-plate rheometry for matrix viscoelasticity, or liquid-like viscous and stiffness-related elastic characteristics. The characterization reveals averaged information and sample-to-sample variation, yet, it neglects internal heterogeneity within matrices, experienced by cancer cells in 3D culture.

### SUMMARY

According to some aspects, there is provided the subject-matter of the independent claims. Some embodiments are defined in the dependent claims.

According to a first aspect of the present disclosure, there is provided a magnetic microrheometry method for estimating microscale microscale viscoelasticity, the method comprising obtaining a 3D culture matrix comprising magnetic spheres, said magnetic spheres having a sphere diameter, exerting a sinusoidally varying magnetic force using a microrheometer thereby causing sinusoidally varying displacement of the magnetic spheres in the 3D culture matrix, measuring the displacement of said magnetic spheres, and estimating microscale viscoelasticity heterogeneity within the 3D culture matrix based at least on the exerted magnetic force and the measured displacement of said magnetic spheres.

### BRIEF DESCRIPTION OF THE DRAWINGS

FIG. 1A-1E illustrates a microrheometry technique and experimental design for quantifying spatially differing microscale viscoelasticity.

FIG. 2 illustrates heterogeneity model definition for quantifying spatial variation of viscoelastic parameters in 3D culture matrices.

FIG. 3 illustrates microrheometer calibration based on volumetric force (\hat{F}_{volumetric}) and phase angle (φ) as a function of varied currents (i_{grad}).

FIG. 4 shows that multilevel Bayesian model enables distinguishing of the heterogeneity in matrix viscoelasticity from the effects of experimental design and measurement errors.

FIG. 5 illustrates sample-to-sample variation in microrheology experiments based on the hierarchical Bayesian model.

FIG. 6 illustrates pointwise microscale viscoelasticity measurements of breast tumor tissue-relevant stiffness levels.

FIG. 7 illustrates Comsol simulation of magnetic-field gradients.

FIG. 8: Model 2 definition.

FIG. 9: Model 3 definition.

FIG. 10: Model 4 definition.

FIG. 11: Model 5 definition.

FIG. 12: Parallel-plate rheometry of viscoelastic properties of 3D-culture matrices with the spheres, and without the spheres.

FIG. 13 shows a graph of calibration values based on the initial and enhanced estimates of \hat{F}_{volumetric}. The graph compares the \hat{F}_{volumetric} constants by the initial estimate (calculated separately for each sphere) and the enhanced estimate (calculated using Stokes' law).

FIG. 14 illustrates viscoelasticity of the matrix types based on microrheometry and parallel-plate rheometry.

FIG. 15 illustrates absolute shear modulus in relation to the displacement signal amplitude.

FIG. 16 shows SEM micrographs of agarose matrices with the 30 μm and the 100 μm spheres.

FIG. 17 illustrates calibration in respect to volumetric force (\hat{F}_{volumetric}). The \hat{F}_{volumetric} constants are shown as mean and standard deviation values (σ).

FIG. 18 illustrates microrheometry for the viscoelasticity of the matrix types.

FIG. 19 illustrates parallel-plate rheometry for comparing sample-to-sample variation.

FIG. 20 shows model comparisons based on ELPD and standard error. A higher ELPD value indicates better model performance.

FIG. 21 shows comparison of the enhanced (enh.) and initial (init.) estimates of \hat{F}_{volumetric} for the 30 μm and the 100 μm spheres.

FIG. 22 shows number of datapoints from all experiments that have passed the post-processing analysis pipeline

FIG. 23 shows pairwise comparisons of the heterogeneity in viscoelasticity for the different matrix types. Posterior distributions of αₘ^{holder} have been compared to provide a probability value quantifying pairwise differences.

### EMBODIMENTS

The progression of breast cancer involves cancer-cell invasions of extracellular matrices. To investigate the progression, 3D cell cultures are widely used along with different types of matrices. Currently, the matrices are often characterized using parallel-plate rheometry for matrix viscoelasticity, or liquid-like viscous and stiffness-related elastic characteristics. The characterization reveals averaged information and sample-to-sample variation, yet, it neglects internal heterogeneity within matrices, experienced by cancer cells in 3D culture. Techniques using optical tweezers and magnetic microrheometry have measured heterogeneity in viscoelasticity in 3D culture. However, there is a lack of probabilistic heterogeneity quantification and cell-size-relevant, microscale-viscoelasticity measurements at breast-tumor tissue stiffness up to ~10 kPa in Young's modulus. Here, we have advanced methods, for the purpose, which use a magnetic microrheometer that applies forces on magnetic spheres within matrices, and detects the spheres displacements. We present probabilistic heterogeneity quantification using microscale-viscoelasticity measurements in 3D culture matrices at breast-tumor-relevant stiffness levels. Bayesian multilevel modeling was employed to distinguish heterogeneity in viscoelasticity from the effects of experimental design and measurement errors. We report about the heterogeneity of breast-tumor-relevant agarose, GrowDex, GrowDex-collagen and fibrin matrices. The degree of heterogeneity differs for stiffness, and phase angle (i.e. ratio between viscous and elastic characteristics). Concerning stiffness, agarose and GrowDex show the lowest and highest heterogeneity, respectively. Concerning phase angle, fibrin and GrowDex-collagen present the lowest and the highest heterogeneity, respectively. While this heterogeneity information involves softer matrices, probed by ~30 μm magnetic spheres, we employ larger ~100 μm spheres to increase magnetic forces and acquire a sufficient displacement signal-to-noise ratio in stiffer matrices. Thus, we show pointwise microscale viscoelasticity measurements within agarose matrices up to Young's moduli of 10 kPa. These results establish methods that combine magnetic microrheometry and Bayesian multilevel modeling for enhanced heterogeneity analysis within 3D culture matrices.

Changes in mechanical properties of human tissues relate to vital body functions, and the progression of diseases, including cancer. In breast cancer, the cancer cells are surrounded by 3D extracellular matrix, and the matrix's macromolecular organization is associated with mechanical properties that mediate invasion and other critical behaviors of cancer cells. The matrix characteristics have been taken into account in the recent 3D cell and tissue culturing methods that enable mimicking the accurate cancer-cell, protein expression, and critical biological pathways. Yet, this 3D culturing, unlike conventional 2D culturing, typically requires the use of relevant scaffold matrices, which mimic the extracellular matrix within breast tumor tissues.

A variety of matrices is used in 3D cultures to account for the mechanical and biochemical properties within breast tumor tissues. These matrices are often studied for mechanical properties using rheometers, revealing viscoelasticity of the matrix, or its (liquid-like) viscous and (stiffness-related) elastic characteristics, which have been found to mediate invasive cancer-cell migration. Rheometer measurements provide averaged values of viscoelastic properties, accompanied by information of the properties' sample-to-sample variation. Further, recent research shows that the matrix viscoelasticity not only involves sample-to-sample variation, but each of the matrix samples may exhibit internal variation that is referred to as heterogeneity in viscoelasticity. Due to the heterogeneity, viscoelastic properties in multiple 3D-culture matrices vary spatially. Each cell senses the stiffness of its environment at the microscale as well as other viscoelasticity-related properties, and responds to those mechanical stimuli. The heterogeneity of 3D-culture matrices in the context of microscale viscoelasticity is yet to be comprehensively quantified.

Measuring the heterogeneity in viscoelasticity within 3D-culture matrices has mainly been carried out using two microrheological methods, optical tweezers and magnetic microrheometers. Optical tweezers measure at one individual location within a matrix at the time, with optional location-specific calibration for enhanced accuracy. The measurements have mostly been carried out at the sample surface proximity (i.e. experimental depths are, typically, 10-50 μm, and exceptionally, up to 500 μm). Magnetic microrheometers enable simultaneous measurements of multiple locations, and the measurements can be performed within the depth on the order of millimeters. However, magnetic microrheometers cannot currently perform cell-size-scale (1-100 μm) viscoelasticity measurements within 3D-culture matrices that have an elevated stiffness level, a Young's modulus up to ~10 kPa, as in breast tumor tissues.

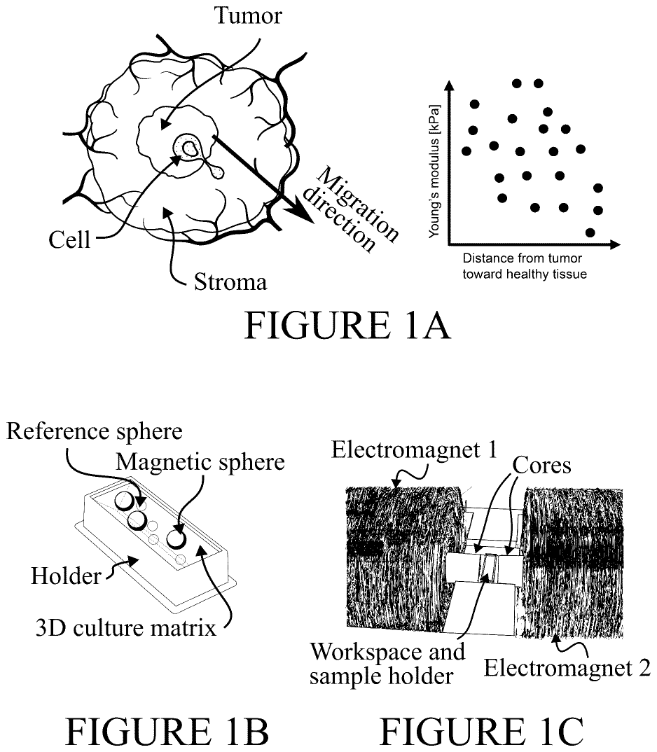

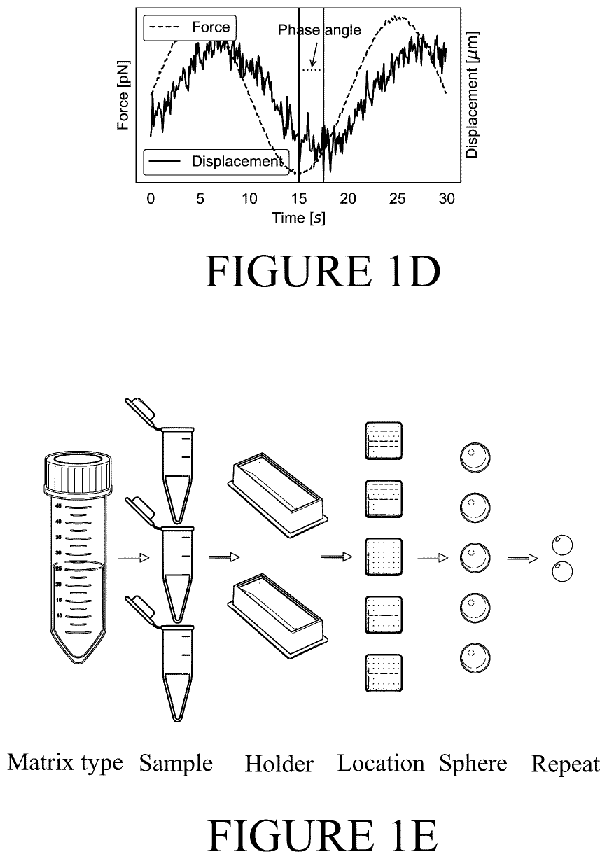

Here, we have developed magnetic-microrheometry methods, based upon, for measurements of microscale viscoelastic properties within 3D-culture matrices that have a range of Young's moduli (E) relevant to breast-tumor tissue, from 100 Pa to 10 kPa (FIG. 1A). The brief operating principle of the used magnetic microrheometer involves exertion of controlled forces onto ~30 μm or ~100 μm diameter magnetic spheres and detection of the sphere-displacement responses. Initially, we calibrated the instrument using silicone oil. Then, we comprehensively quantified heterogeneity in viscoelasticity for the breast tumor tissue-relevant 3D-culture matrices that contain biologically inert agarose and GrowDex, as well as biologically active GrowDex-collagen and fibrin. The heterogeneity quantification involved the use of a Bayesian hierarchical model incorporating the effects of experimental design to enable heterogeneity comparisons of the matrices. Finally, we probed the microscale viscoelasticity inside agarose matrices, providing Young's moduli up to E=10 kPa. The results establish methods that combine advanced magnetic microrheometry and the Bayesian hierarchical model for an enhanced heterogeneity analysis of spatially varying viscoelastic properties within 3D-culture matrices.

FIG. 1. Microrheometry technique and experimental design for quantifying spatially differing microscale viscoelasticity. FIG. 1A: Breast-cancer tumor is surrounded by the stroma consisting of extracellular matrix. The cancer cells migrate out from the tumor, invade the stroma and further tissues during breast-cancer progression. In comparison to healthy tissues, the tumor tissues have often an increased Young's modulus, and other viscoelastic properties also are altered. FIG. 1B: Illustration shows a 3D culture matrix (in red) prepared into a sample holder. Two types of spheres, magnetic and reference spheres, have been introduced in the matrix during its preparation, enabling microscale viscoelasticity measurements using the microrheometer. FIG. 1C: The microrheometer system has two aligned electromagnets with cobalt-iron cores. The sample holders were placed into the working space between the cores. The electromagnets were driven by varied currents to exert forces on the magnetic spheres. FIG. 1D: Illustration of the oscillatory forces that were applied on a magnetic sphere. As a response, the magnetic sphere displaces in respect to reference, provided by reference spheres. The absolute shear modulus was derived using the amplitudes of the force and the displacement, while the phase angle was used as it is (indicated by the black vertical line). FIG. 1E: The sample preparation was carried out as in the multilevel hierarchy. For each matrix type, three samples were prepared, which were aliquoted into two sample holders per sample. Then, measurements were performed for 3-5 locations (field of view) within each holder. Two repetitive measurements were provided.

We quantified the heterogeneity in microscale viscoelasticity based on measurement spheres within breast tumor tissue (FIG. 1A) relevant 3D-culture matrices (FIG. 1B), and the use of the magnetic microrheometer (FIGS. 1C & 1D). Bayesian multilevel modeling was applied for the obtained microrheometry data to account for the experimental design (FIG. 1E) and extract relevant heterogeneity metrics at stiffness levels up to a shear modulus (G) of 0.4 kPa. The ≅30 μm magnetic spheres used in the heterogeneity quantification experience insufficient forces to induce detectable displacements at higher stiffness levels (i.e. G>0.4 kPa). Therefore, larger spheres, the ~100 μm magnetic spheres, were used to increase the magnetic volume-dependent forces, responsible for the displacements. Thus, measurements were demonstrated at the breast-cancer tumor tissue-relevant stiffness levels (i.e. up to shear moduli (G) of 3.5 kPa, or Young's moduli (E) of 10-11 kPa). The microscale viscoelasticity measurements were validated using conventional parallel-plate rheometry.

We incorporated measurement spheres within the matrices to quantify the matrix heterogeneity. We used two sphere types, magnetic and non-magnetic spheres, which had the final volume fractions of 0.06% and 0.03%, respectively. The magnetic spheres were composed of iron oxide and poly(lactic acid), and had mean nominal diameters of either 30 μm (Micromod GmbH, 12-00-304), or 100 μm (Micromod GmbH, 12-00-105), which we refer to as ‘the 30 μm magnetic spheres’ and ‘the 100 μm magnetic spheres’, respectively. Uncoated magnetic spheres were used for all matrices, except for agarose, which required coating with NH₂ groups to achieve homogeneous dispersion.

Non-magnetic spheres with a nominal mean diameter of 6.0 μm were used in all matrices to provide a reference location for the magnetic probes in order to remove mounting-related and environmental vibrations. The suspension containing either the 30-μm- or the 100-μm-diameter magnetic spheres, accompanied by the non-magnetic spheres, is referred to as ‘sphere suspension’.

We used four types of 3D culture matrices-agarose, GrowDex (nanofibrillar cellulose), double-network GrowDex-collagen, and fibrin-that contained the sphere suspension. For the microrheometry measurements, the matrices were prepared in 25×4.5×3.3 mm³ polymethylmethacrylate holders that had a microscopy cover glass glued underneath.

For agarose matrices, the stock solution was prepared by dispersing ultrapure low melting point agarose (Invitrogen, 16520050) in Milli-Q water. The solution was placed in a water bath at 80° C. until the powder dissolved. The warm solution was immediately mixed with the required amounts of the sphere suspension to achieve the desired final concentration of agarose: 0.5%, 0.9%, 1.0%, 1.1%, 1.25%, and 1.35%. Before the sample solution cooled down, it was pipetted into the sample holders. The sample was then allowed to gel at room temperature for 50 minutes. The heterogeneity quantification employed the 30 μm magnetic spheres for the 0.5% agarose, whereas the pointwise microscale viscoelasticity measurements used the 100 μm magnetic spheres for the rest of the agarose concentrations.

GrowDex matrices were prepared using a 1.5% GrowDex product (UPM Kymmene Oyj, 100103002) by diluting the product to a concentration of 1.25%. The required volumes of Milli-Q water and non-magnetic spheres were transferred into one mixing syringe, and a female-to-female Luer lock connector was attached. Subsequently, the 1.25% GrowDex solution was aliquoted into another mixing syringe, and the 30 μm magnetic spheres were added directly into the GrowDex solution, to prevent adhesion of the spheres to the plastic parts of the syringe. The two syringes were then connected, and the contents were mixed 50 times, by alternately pushing the syringe plungers, to homogenize the sample. The contents were finally aliquoted into sample holders and let sit for 30 minutes at the room temperature before the measurements.

Double-network GrowDex-collagen matrices were prepared using a 1.5% GrowDex product and a rat-tail collagen type I product (Corning, 354236) that were diluted to a 0.45% solution and a 2.0 mg/mL concentration, respectively. The pH was maintained at ≅8. The required volumes of DMEM/F12 medium, non-magnetic sphere suspension, GrowDex, and 1.045% NaOH were transferred into the first mixing syringe and a Luer lock connector was attached. Subsequently, the collagen type I was aliquoted into the second mixing syringe and the 30 μm magnetic sphere suspension was added directly into the solution. Then, the syringes were connected, and the two constituents were mixed 50 times for homogenization. The solution was promptly aliquoted into sample holders and allowed then for polymerization at 37° C. for 50 minutes.

We use fibrin data to compare with other 3D culture matrices. The fibrin matrix preparation behind the data is described at PLOS One article by O. Arasalo and A. J. Lehtonen et al. (2023) (accepted) (DOI: 10.1371/journal.pone.0282511)

A SEM (Zeiss Sigma VP FEG) was used to characterize the morphology of the magnetic spheres and the surrounding matrices (i.e. the 30 μm spheres in a 0.5% agarose matrix, and the 100 μm spheres in a 1.0% agarose matrix). These samples were prepared for the SEM as followed. First, the samples were gradually dehydrated with a series of ethanol concentrations (10, 30, 60, 80, 90 and 100%), each for 1 day at room temperature.

Subsequently, they were dried using the critical point method, to minimize the morphological alterations commonly caused by lyophilization. Loose magnetic spheres were collected with magnet. These dried samples were mounted on stubs using carbon tape, sputter coated with 5 nm of Pt/Pd, and finally imaged using the SEM.

Microscale viscoelastic properties of the 3D culture matrices were measured using the matrix-embedded magnetic spheres and a previously developed magnetic microrheometer [33]. The instrument was modified to use a Basler 3.2MP microscope camera on a Zeiss Axiovert 200M microscope. The microrheometer had electromagnets with an outer and inner diameters of 80 mm and 6 mm, respectively, with lengths of 47 mm, which were positioned to generate a cylindrically symmetric magnetic field along the axis perpendicular to the electromagnet cross section. The two electromagnets had cobalt-iron cores (Vacuumschmelze, Vacoflux 50), with diameters of 6 mm, and lengths of 65 mm. The inner blunt sides of the cores were placed 7 mm from each other to provide a space for the sample holder.

The measurements were based on the exertion of magnetic forces by the microrheometer (i.e. micromanipulator type 1). The microrheometer exerted forces on the magnetic spheres within the matrices, via the generation of magnetic-field gradients and constant magnetic fields by the electromagnets, as described in [33, 45]. Briefly, the field gradients tune the forces exerted on the magnetic spheres, of which magnetization is set by the fields. These force-generating field gradients and the fields can be separately adjusted using superpositioned currents (Eqs. 1-2), fed to the electromagnets.

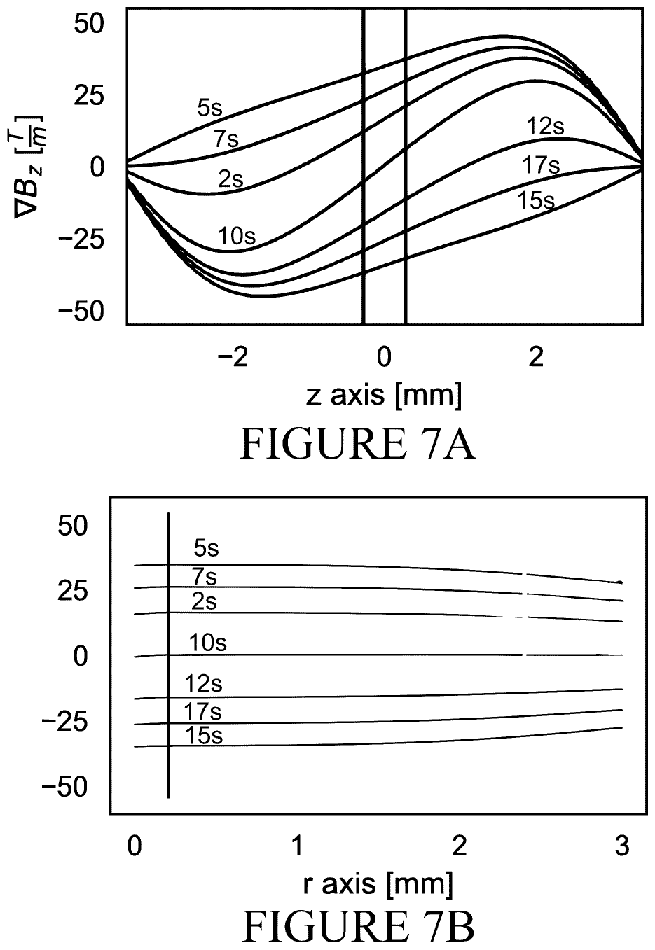

Previous works by Pokki et al. [33, 45] provide a detailed characterization of the homogeneity of magnetic fields and magnetic-field gradients for the microrheometer system type. In this work, we simulated the microrheometer system according to the ref. [46] to model the force-altering magnetic-field gradients during the sinusoidal current sequence. FIGS. 7A & 7B show these simulation results for magnetic-field gradients (∇B_{z}). Cylindrical coordinates were used and a rotational symmetry was assumed (i.e. z axis and x axis are parallel and perpendicular to the electromagnet core's long axis, respectively). The simulations were performed to the sinusoidal current sequence used in the experiments (i.e. sinusoidal amplitude based on i_{grad}=1.25 A, and a constant i_{field}=0.75 A maintained the magnetic-sphere magnetization; see Eqs. 1-2). The workspace is indicated with vertical lines. The simulation's workspace is relevant to the field of view of the experiments (i.e. 560 μm×420 μm). Further, the matrix types are elastically dominated materials (i.e. phase angle (φ) is less than) 20°. Therefore, the relevant homogeneity of the field gradients (∇B_{z}) is for the maximal/minimal field gradients generating maximal/minimal forces on the magnetic spheres (FIGS. 7A & 7B; time points of 5 s and 15 s). Thus, these field gradients correspond to the peak-to-peak values of the sinusoidal displacement responses. The homogeneity of the force-generating field gradients (∇B_{z}) around the center of workspace is ±12%. Within this workspace, Pokki et al. report symmetrical magnetic fields and a high degree of homogeneity of the fields.

This force generation by the two electromagnets was controlled by two distinct currents, driven by linear amplifiers using bipolar 40 V power supplies (GW, SPD-3606). The current-controlled forces were applied on the magnetic spheres. A Labview program and a DAQ card (National Instruments, PCIe-6341) were used to set the two time-varying currents fed to the electromagnets 1-2 to generate the forces and induce magnetic-sphere displacements (FIG. 1C).

The currents supplied to both electromagnet coils (i_{coil1} and i_{coil2}) used an equal offset (i_{offset}) values of 0.75 A. Each offset value was superpositioned by a sinusoidally varying current (i_{grad}) with an amplitude of 1.25 A and a frequency of f=0.05 Hz:

$${i}_{coil 1} = {i}_{offset} + {i}_{grad} \qquad ( Eq . 1 )$$

$${i}_{coil 2} = {i}_{offset} - {i}_{grad} \qquad ( Eq . 2 )$$

The magnetic spheres were tracked in respect to the non-magnetic reference spheres, using recorded videos. The tracked displacements (pₛₚₕₑᵣₑₛ) were fit to the following equation:

$${p}_{spheres} = {\hat{p}}_{spheres} sin ( 2 πft - ϕ ) , \qquad ( Eq . 3 )$$

where \hat{p}ₛₚₕₑᵣₑₛ is the amplitude of the displacement signal, f is the frequency, φ is the phase angle between the applied force and the observed displacement, and t is time.

The absolute shear modulus (|G|) was calculated based on the fitted \hat{p}ₛₚₕₑᵣₑ values:

$$\vert G \vert = \frac{{\hat{F}}_{volumetric} {V}_{sphere}}{3 π {D}_{sphere} {\hat{p}}_{sphere}} \qquad ( Eq . 4 )$$

where \hat{F}_{volumetric} is the volumetric force constant derived during the calibration, Vₛₚₕₑᵣₑ is each magnetic sphere's volume, and Dₛₚₕₑᵣₑ is the diameter of each magnetic sphere. NB: The volumetric force constant denotes for

$${\hat{F}}_{volumetric} = \frac{{\hat{F}}_{sphere}}{{V}_{sphere}} ,$$

where \hat{F}ₛₚₕₑᵣₑ is the magnetic-force amplitude exerted on each magnetic sphere.

To compare to breast-cancer tissue stiffness, the calculated |G| values of agarose matrices were converted to Young's modulus (E) values assuming that the Young's modulus is equivalent to the absolute Young's modulus (i.e. E=|E|):

$$E = 2 ( 1 + v ) \vert G \vert \qquad ( Eq . 5 )$$

where v is the Poisson's ratio of the agarose matrices (i.e. v=0.37-0.50).

The microrheometer was initially calibrated in respect to the instrument-generated magnetic forces, and the phase angle. The calibration was realized by using dried magnetic and reference spheres that were resuspended in silicone oil with known viscous properties (i.e. dynamic viscosity of μ=30 000 cSt; Sigma, 63148-62-9). The silicone oil, containing the dried spheres, was aliquoted into the sample holders.

During the calibration, we determined the working space, and quantified subsequently the average magnetic-force amplitude acting on the distinct-sized magnetic spheres within the workspace (i.e. the average volumetric force constant \hat{F}_{volumetric}). Briefly, the calibration protocol involved exerting the current-controlled, sinusoidal magnetic forces on the magnetic spheres in silicone oil, and tracking the magnetic-sphere displacements in respect to reference spheres, enabling derivation of the \hat{F}_{volumetric}. The volumetric force constant was calculated based on the Stokes' drag force (i.e. F_{d}=3πμDₛₚₕₑᵣₑ\hat{v}ₛₚₕₑᵣₑ, where μ is the dynamic viscosity of the silicone oil at room temperature, and \hat{V}ₛₚₕₑᵣₑ is the average fitted velocity amplitude of a magnetic sphere). Thus, the volumetric-force constant is:

$${\hat{F}}_{volumetric} = \frac{{F}_{d}}{{V}_{sphere}} = \frac{3 {πμ D}_{sphere} {\hat{v}}_{sphere}}{\frac{4}{3} {π ( {D}_{sphere} / 2 )}^{3}} = 18 μ \frac{{\hat{v}}_{sphere}}{{D}_{sphere}^{2}} \qquad ( Eq . 6 )$$

This relation shows that—for a constant \hat{F}_{volumetric}—the velocity amplitude (\hat{v}ₛₚₕₑᵣₑ) of each magnetic sphere has a linear relation with the squared diameter of the sphere

$$( {D}_{sphere}^{2} ) ,$$

as well as with the squared sphere radius

$$( {r}_{sphere}^{2} = {( \frac{{D}_{sphere}}{2} )}^{2} ) .$$

Thus, instead of calculating \hat{F}_{volumetric} separately for each magnetic sphere, we have estimated the slope (β) between the two variables (β=\hat{v}ₛₚₕₑᵣₑrₛₚₕₑᵣₑ²) to get a more robust estimate of the \hat{F}_{volumetric} constant for calibration. Thus, we have fitted a simple linear regression model without an intercept. The model is as follows:

$$β ∼ N ( 0 , 5000 ) , \qquad ( Eq . 7 )$$

$$σ ∼ Inverse - Gamma ( 0.5 , 1 ) \cdot {10}^{- 8} \qquad ( Eq . 8 )$$

$${\hat{v}}_{sphere} ∼ N ( β {r}_{sphere )}^{2} , {σ}^{2} ) \qquad ( Eq . 10 )$$

where σ is an unknown standard deviation. The model's prior choices have been scaled to match the scale of the data. The model assumes a Gaussian likelihood. Given the model, the \hat{F}_{volumetric} constant is simply the following:

$${\hat{F}}_{volumetric} = \frac{9}{2} βμ .$$

The goodness of fit has been assessed with a Bayesian R² value. In addition to this \hat{F}_{volumetric} constant calculation, the distribution of the phase angles (φ) for each magnetic sphere was recorded to evaluate the measurements uncertainty.

In this work, the phase angle (φ) was used in the analysis instead of the conventional loss tangent (tan (φ)). For describing the ratio between the viscous and elastic characteristics, the phase angle was considered simpler, since it is also descriptive for purely viscous materials (φ=90°)—such as the silicone oil—that have infinite loss-tangent values.

The experimental design followed the hierarchy specified in FIG. 1E. For each matrix type, we prepared three samples, and each sample was split to two sample holders. For each sample holder, 3-5 locations containing 1-3 magnetic spheres were measured at room temperature. The samples that failed to polymerize normally (≅0 Pa) or contained the spheres mostly at the bottom of the sample holder were unused in the further analysis.

The measurements were carried out at the linear viscoelasticity regime, since the forces exerted by the microrheometer provide small displacements within the matrices, specifically, the 30 μm and the 100 μm magnetic spheres displace at the most hundreds of nanometers. By using these small forces/displacements, we avoid detection of nonlinearities in the matrix viscoelastic properties (e.g. for agarose), develop a measurement protocol that would minimize distraction to cells due to sphere motion in 3D culture, and avoid unnecessary heating of the electromagnets applying the forces. According to Eq. 4, the 100 μm spheres are expected to measure ~8 times larger |G| values in comparison to the 30 μm spheres (i.e. |G_{100 μm}||G_{30 μm}|≅8). The measured viscoelastic properties can be assigned to specific points within the matrix, whereas-in an ideal homogeneous material-such values are constant at each point/location. The most of the used 3D culture matrices are known to exhibit heterogeneous or spatially varying viscoelastic properties.

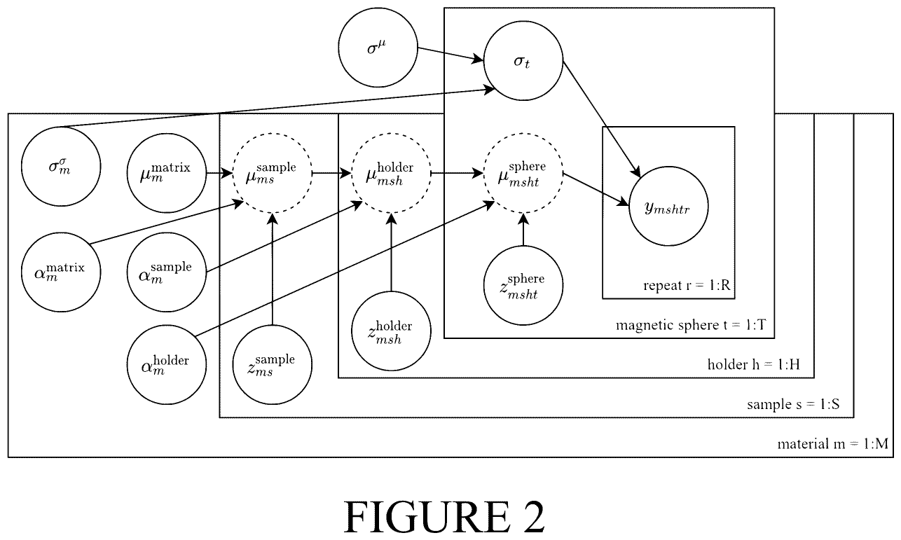

Conventional metrics of defining heterogeneity, such as coefficient of variation, have challenges in interpretability and they may include combined information of both spatial variation and experimental uncertainty. We captured the 3D culture matrices' heterogeneity of microscale viscoelasticity, using a Bayesian multilevel model, separating the spatial variation from the known experimental uncertainty. The experimental design structure (FIG. 1E) can be incorporated into this model to robustly estimate the heterogeneity. The Bayesian paradigm was chosen due to its strength in quantifying uncertainty, which is especially important since the data sizes were relatively small (i.e. 3 samples per matrix type). The 3D culture matrices' heterogeneity was assumed to manifest itself at the sample-holder level, therefore, the heterogeneity is defined as the magnitude of the spatial variation in viscoelastic properties within a sample holder. The used model is summarized in FIG. 2 and explained in detail in the following paragraphs. The model variables are listed below:

$$\begin{matrix}{μ}_{m}^{matrix} , {z}_{ms}^{sample} , {z}_{msh}^{sphere} , {z}_{msht}^{sphere} \sim N ( 0 , 1 ) & Level effect priors\end{matrix} \qquad ( Eq . 10 )$$

$$\begin{matrix}{α}_{m}^{matrix} , {α}_{m}^{sample} , {α}_{m}^{holder} \sim HalfNormal ( 0 , 1 ) & Level effect priors\end{matrix} \qquad ( Eq . 11 )$$

$$\begin{matrix}{σ}_{m}^{σ} , {σ}^{μ} \sim HalfNormal ( 0 , 1 ) & Noise priors\end{matrix} \qquad ( Eq . 12 )$$

$$\begin{matrix}{σ}_{t} \sim InverseGamma ( {σ}^{μ} , {σ}_{m} σ ) & Measurement noise\end{matrix} \qquad ( Eq . 13 )$$

$$\begin{matrix}{μ}_{ms}^{sample} = {μ}_{m}^{matrix} + {α}_{m}^{matrix} {z}_{ms}^{sample} & Sample effect\end{matrix} \qquad ( Eq . 14 )$$

$$\begin{matrix}{μ}_{msh}^{holder} = {μ}_{ms}^{sample} + {α}_{m}^{sample} {z}_{msh}^{holder} & Holder effect\end{matrix} \qquad ( Eq . 15 )$$

$$\begin{matrix}{μ}_{msht}^{sphere} = {μ}_{msh}^{holder} + {α}_{m}^{holder} {z}_{msht}^{sphere} & Sphere effect\end{matrix} \qquad ( Eq . 16 )$$

$$\begin{matrix}{y}_{mshtr} \sim N ( {μ}_{msht}^{sphere} , {σ}_{t} ) & Likelihood\end{matrix} \qquad ( Eq . 17 )$$

FIG. 2. Heterogeneity model definition for quantifying spatial variation of viscoelastic parameters in 3D culture matrices. The mean value of each magnetic sphere is estimated as a sum of multiple level effects. There are m different matrix materials, h holders, s samples, h magnetic beads, and r repeats. Different 3D matrix material types are independent of each other, apart from sharing a common mean noise term. Partial pooling is used for each level of hierarchy to improve robustness. Specific level effects are denoted by a parameter vector u, where the superscript is the level, and the subscript is the parameter corresponding the given observation (m, h, s, or t). The scale of the effect is provided by a with analogous super/subscripts. Non-centered parametrization is used for the level effects that are denoted using dotted lines (Eq. 14). This model is run separately for estimating the absolute shear modulus (|G|) and the phase angle (φ) (denoted by y with subscripts). The gray color indicates observations (i.e. either |G|, or φ). The used data has been z-score normalized.

We quantified the heterogeneity in viscoelasticity using this multilevel model that has the level effect priors as in Eqs. 10-11. Specifically, we extracted the 3D culture matrix type-specific αholder m value for both |G| and φ data (Eq. 11). The matrix type-specific values were used to provide the heterogeneity information within each holder, accounting for the uncertainty (Eqs. 12-13) and the experimental design (Eqs. 14-16). The likelihood was chosen to be a Gaussian distribution (Eq. 17).

This primary model was constructed as a three level, linear random intercept model with partial pooling at each level. The levels were chosen to account for the errors in experimental design. As demonstrated in FIG. 1D, each matrix type condition was divided into samples (s=1, . . . , S), which consisted of holders (h=1, . . . , H), locations within holders, and finally, repeated measurements (r=1, . . . , R) by individual magnetic spheres within each location (t=1, . . . , T). The model estimated the viscoelastic properties based on the magnetic spheres, by computing the sum of the sample, sample holder, and sphere level information (Eqs. 14-16). Each parameter is a vector and the subscript denotes the correct index for the ith observation. For instance,

$${μ}_{msht}^{sphere}$$

means the magnetic sphere effect for the mth material/condition (e.g agarose), sth sample, hth holder and tth magnetic sphere within the described nested structure.

The location level was unaccounted in this primary model due to the following challenges in the results interpretability. If the location level had been used, the matrix heterogeneity would have most likely been an underestimate of the total spatial variation. Additionally, the parameter of interest would have been the location-dependent variation, which is problematic as the experimental protocol typically enabled 1-3 measurements of the 30 μm magnetic spheres in a location. Further, the parameter describing the variation in viscoelasticity within a holder would irrelevantly represent the variation between locations.

The measurements included noise for the detected displacements of each magnetic sphere. Therefore, each measurement by a magnetic sphere was replicated at least two times to enhance accuracy. The measurement uncertainty differed between magnetic spheres, due to the errors in the particle tracking. Therefore, a separate noise term was introduced for each individual magnetic sphere. Similarly as the level estimates, this noise term σₜ was partially pooled to improve robustness. The mean noise level, indicated by σ_{μ}, was shared over 3D-culture matrices as it is reasonable to consider the mean noise level to be invariable, because the same microrheometer system was used. On the other hand, the variation of the noise (σₘ^{σ}), is independent for each material, owing to random effects caused by the distinct properties of the matrices.

For numerical stability, the data (|G| and φ) was z-score normalized. The normalization's standard deviation was the same for each individual 3D culture matrix to keep the comparison of the heterogeneity comparable. In contrast, the normalization used the mean values of each matrix. NB: The magnitudes of the 3D culture matrix properties were irrelevant in this heterogeneity quantification. Further, accompanied by this normalization, the level effects were reparameterized with non-centered parametrization, as explained in. The model was written in Stan probabilistic programming language and sampled with the default Hamiltonian Monte Carlo parameters provided by the Stan library.

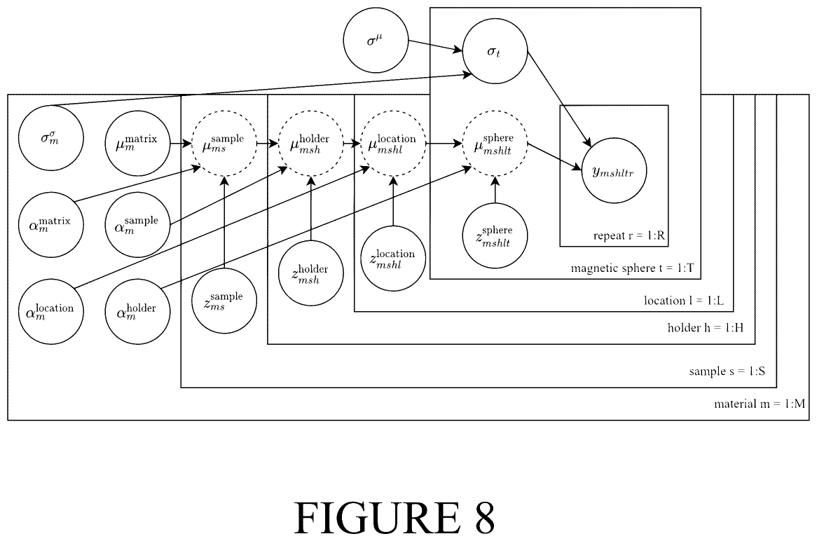

The model performance was validated by confirming that the Markov Chain Monte Carlo (MCMC) algorithm had explored the parameter space fully and converged. An out-of-sample predictive performance was estimated with expected log pointwise predictive density (ELPD). This was done via a cross validation by leaving one magnetic sphere out at a time. The model was also compared against other versions of the hierarchical model to validate the model choices as described below (FIGS. 8-11 for all model specifications).

Initially, the primary model (model 1, FIG. 2) was compared against a model with an additional location level effect (model 2, FIG. 8). The interpretation of the parameters changes in the model 2, where the variable

$${α}_{m}^{holder}$$

(Eq. 11) lacks itself to indicate the material heterogeneity but rather the variation of locations within each sample. NB: The additional location-level effect

$$( {α}_{m}^{location} )$$

captures the variation in viscoelasticity based on the spheres within a location. On the other hand, the used model 2 captures the experimental-design effects in

$${α}_{m}^{holder} .$$

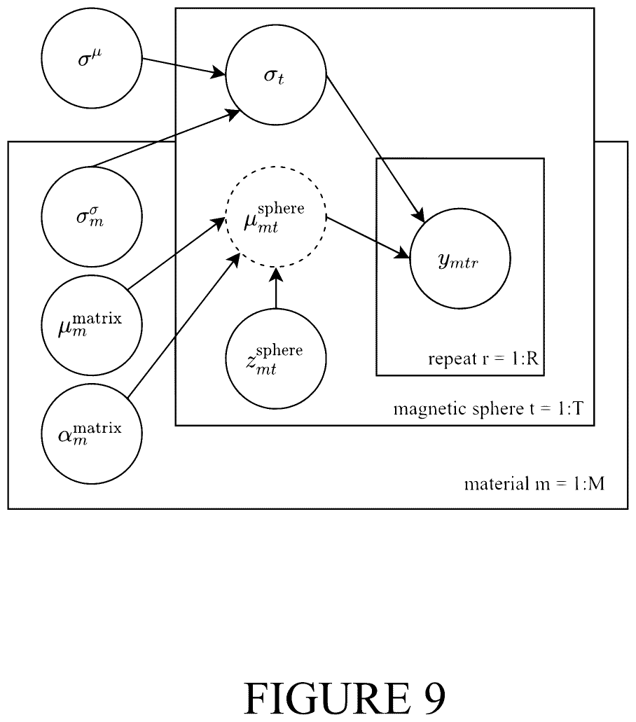

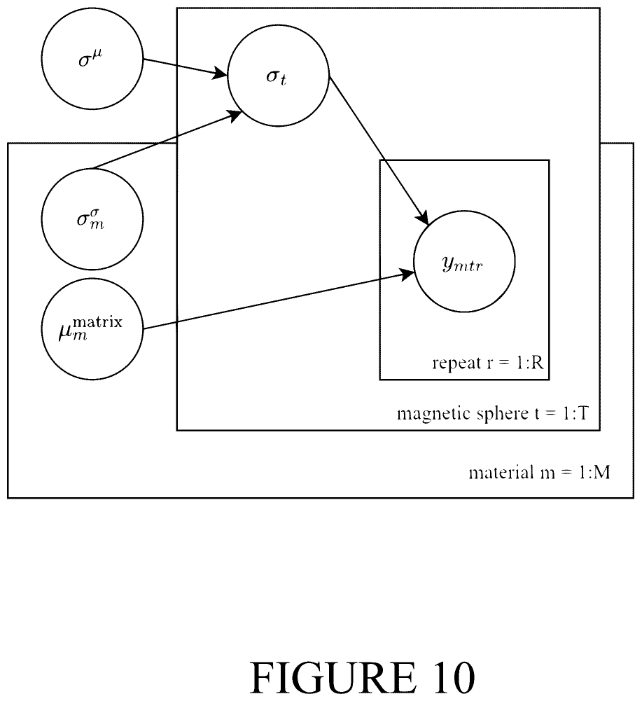

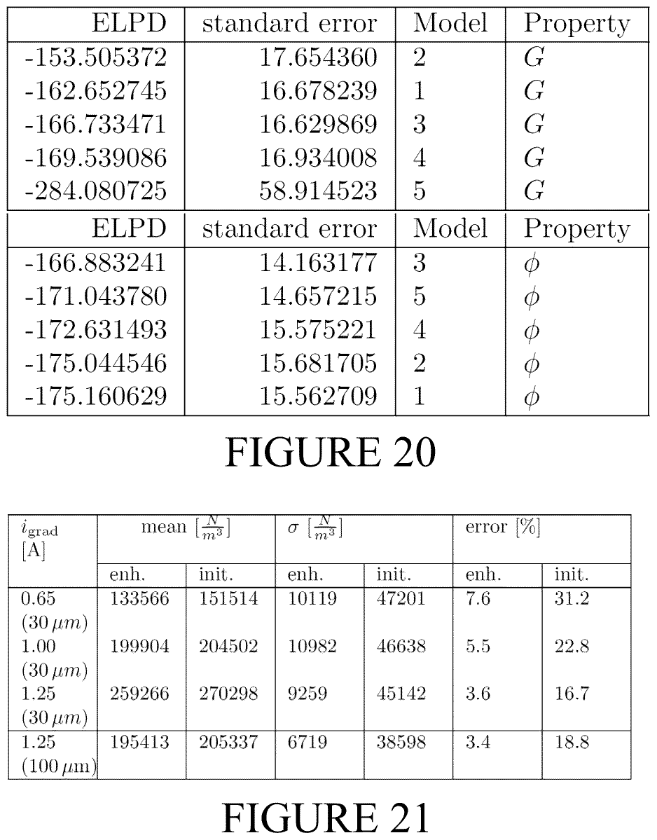

Then, comparisons were performed against three further models (models 3-5, FIGS. 9-11) that are expected to overestimate the heterogeneity as they are incapable of accounting for the effects of experimental design. The primary model (model 1) was compared against the model 3 with only a single level of hierarchy assuming no sample, holder or location level effects. For the model 4 (baseline), the primary model (model 1) was compared against the fully pooled model 4 where the material had a single mean value (of |G| or φ) and the standard deviation of the mean indicated the matrix heterogeneity. The importance of the pooled noise term (model 5) was also confirmed by removing it from the baseline model (model 4) as specified in FIG. 10. FIG. 20 provides further details on the model comparisons.

Additionally, the primary hierarchical model results were compared against measurements from parallel-plate rheometry. As discussed earlier, the conventional parallel-plate rheometry is unable to capture the samples' internal spatial heterogeneity, but quantifies the sample-to-sample variation. Thus, we analyzed the microrheometry data by using the hierarchical model's estimate of the sample-to-sample variation

$$( {α}_{m}^{sample} ; FIGURE 2 )$$

for comparison to the parallel-plate rheometry data based on the conventional coefficient of variation (i.e. the ratio between standard deviation and mean).

A rheometer (Physica MCR 302 rheometer, Anton Paar), with a parallel plate of 25 mm in diameter, was used to validate the microrheometry results of the 3D culture matrices. The rheometry experiments were carried out as follows. A volume of 1 mL of a pre-gel matrix solution was deposited onto the bottom plate of the rheometer. The upper smooth plate of the rheometer was immediately lowered to the desired gap height of 1 mm. The excess sample was trimmed from the edges, and an oil enclosure was formed around the sample to prevent water evaporation. Time sweeps were performed at a strain amplitude of 1%, using a frequency of 0.05 Hz, at a temperature of 25° C. The absolute shear modulus and the phase angle were measured every 1 min throughout the gelation process, until the sample reached an equilibrium state or the measurements were stopped after 90 minutes.

This protocol had minor exceptions in the measurements of GrowDex-collagen and fibrin matrices. The GrowDex-collagen matrices were measured using two temperature intervals (at a frequency of 0.05 Hz). During the first interval lasting for 40 min, the temperature was set to 37° C. to let collagen to polymerize. In the second interval, lasting from 40 min to 90 min, the temperature was set to 25° C. Further, the rheological properties information of the fibrin matrices is as in the public repository: https://osf.io/jsxqh/(DOI: 10.17605/OSF.IO/JSXQH). The parallel-plate rheometry characterization of the fibrin matrices is explained in the PLOS One article by O. Arasalo and A. J. Lehtonen et al. (2023) (accepted) (DOI: 10.1371/journal.pone.0282511).

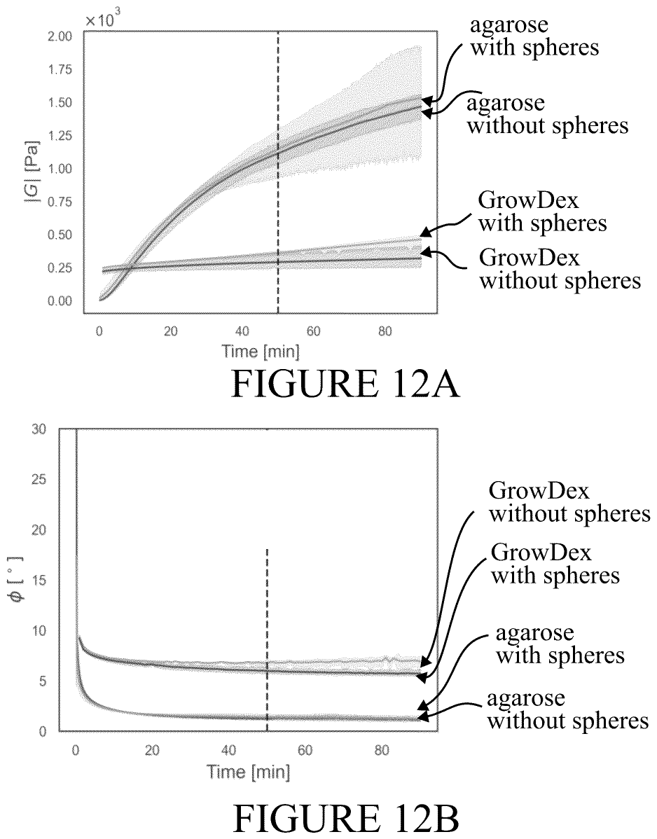

In addition, we investigated the effects of the magnetic and reference spheres on the rheology of agarose and GrowDex matrices. These matrices were prepared with and without the spheres, and measured using the parallel-plate rheometer (FIG. 12). The samples with the spheres were prepared and measured as described before, but—for the samples without the spheres—the volume taken by the spheres was replaced with Milli-Q water.

The results include the microrheometer calibration and the quantification of heterogeneity in viscoelasticity for the different 3D culture matrix types. Further, the pointwise microscale viscoelasticity at tumor-relevant stiffness levels is revealed, via increased magnetic-force measurements, obtained by enlarging the magnetic-probe nominal diameter, from 30 μm to 100 μm.

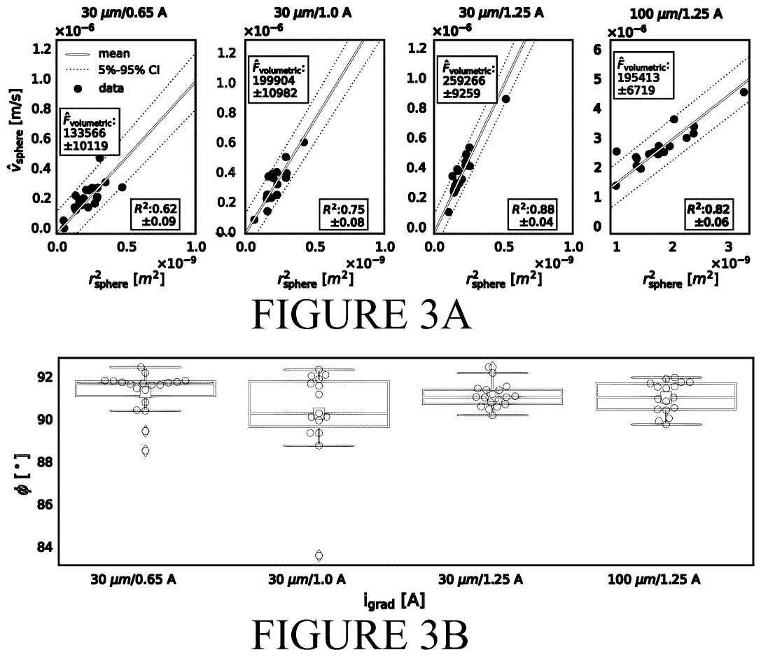

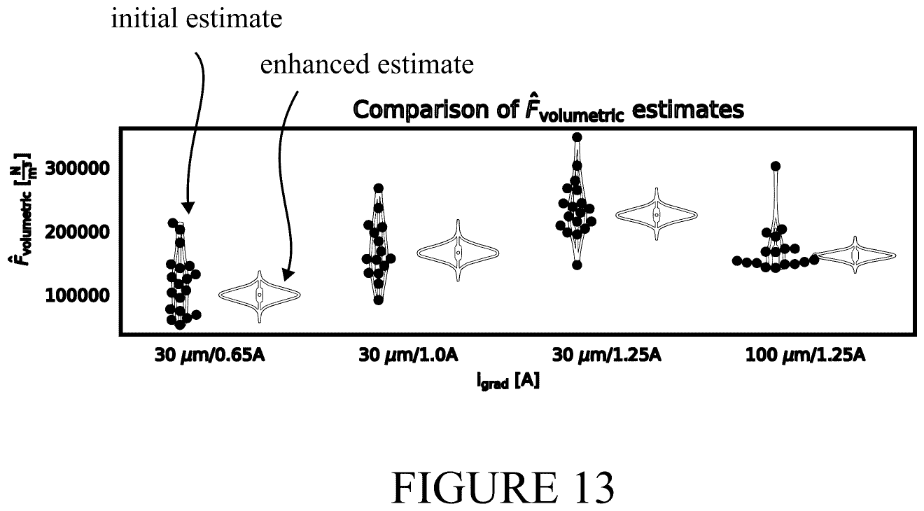

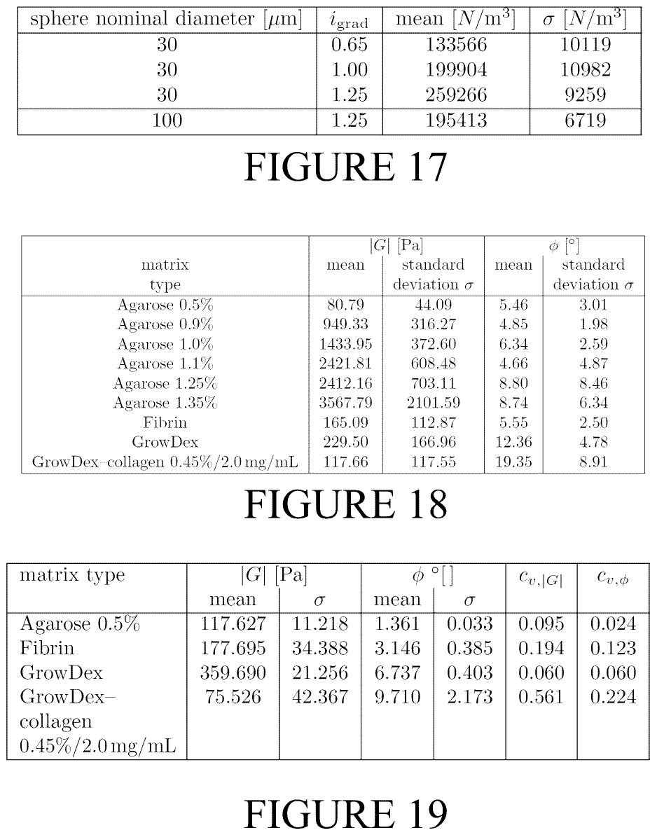

The microrheometer calibration involves the determination of the relationship between the electromagnet current i_{grad}, and the force applied on the magnetic spheres within the silicone oil. We report on the use of force-adjusting, electromagnet currents i_{grad}=0.65 A, i_{grad}=1.00 A, and i_{grad}=1.25 A, and measurements of the volumetric force \hat{F}_{volumetric}) (FIGS. 3A and 17) and the phase angle (φ) (FIG. 3B). As the magnetic spheres have differences in radii that scales the magnetic volume, the volumetric forces exerted on the spheres have been quantified by accounting for both the varying radii and the volume (Eqs 6-9). Specifically, determining linear fits between the squared sphere radii and averaged velocity amplitude of the spheres enables extraction of the volumetric force (FIG. 3A and Eq 7). The data follows the linear trend for all the datasets and the fits have an increasing certainty for the volumetric forces at elevated currents i_{grad}. Further, FIG. 3A shows that the current i_{grad}, related to magnetic-field gradient, expectedly adjusts the volumetric force applied on the spheres. FIG. 17 shows the calibration of the \hat{F}_{volumetric} constant values derived from the slopes of the linear fits for both the 30 μm and 100 μm magnetic spheres. Additional comparisons against another, less accurate estimate of the \hat{F}_{volumetric} constant calculated as magnetic-sphere specific values is in FIG. 8 and FIG. 13. FIG. 3B shows phase-angle values that are distributed around the predicted value of 90° for purely viscous fluids, and the values are independent from i_{grad}.

FIG. 3. Microrheometer calibration based on volumetric force (\hat{F}_{volumetric}) and phase angle (φ) as a function of varied currents (i_{grad}). A: Relation between the squared sphere radius

$$( {r}_{sphere}^{2} )$$

and the average sphere velocity (\hat{v}ₛₚₕₑᵣₑ) is shown as black spheres. The R² values show the goodness of fit of the linear curves. The red shadowed areas indicate the credible intervals of the estimates. Increasing the value of i_{grad} enlarges the measured volumetric forces (i.e. steeper slope) exerted onto the magnetic spheres, as previously reported [45]. As the calibration for both the 30 and 100 μm spheres, the \hat{F}_{volumetric} constant values at i_{grad}=1.25A were calculated based on the linear fits (red line), and used in all further experiments. B: Relation between the phase angle (φ) and the current igrad is presented. The measurements are scattered around the ideal value of 90° for purely viscous materials. The dark grey spheres show the φ values measured by individual magnetic spheres, while the red squares are the mean values of the spheres. Standardly, the plots' box and whiskers indicate the lower/upper extremes, the 25% and the 75% percentiles, and the median. Each dataset indicates whether the calibration is for the 30 μm or the 100 μm spheres.

FIG. 17. Calibration in respect to volumetric force (\hat{F}_{volumetric}). The \hat{F}_{volumetric} constants are shown as mean and standard deviation values (σ).

All further experiments are carried out at i_{grad}=1.25 A, providing the highest force for maximal displacement signal-to-noise ratio. The mean±standard deviation values of the volumetric force for the 30 μm and 100 μm magnetic spheres are \hat{F}_{volumetric,30},=2.59.105 N/m³±0.09·10⁵ N/m³ and \hat{F}_{volumetric,100}=1.95·105±0.07·105 N/m³, respectively. The volumetric-force uncertainty is described by the ratio between standard deviation and mean: 3.6% for the 30 μm magnetic spheres, and 3.4% for the 100 μm magnetic spheres (FIG. 17). The volumetric forces correspond to maximum forces of 12.8 nN for the 30 μm spheres, and 154.2 nN for the 100 μm spheres.

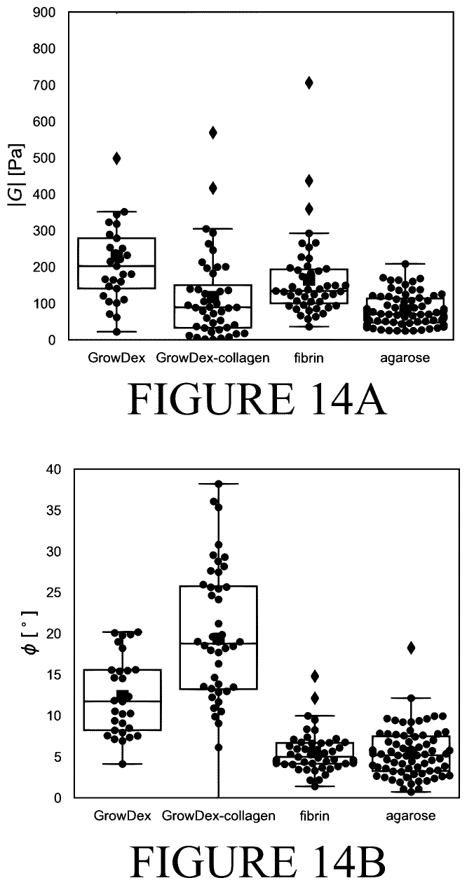

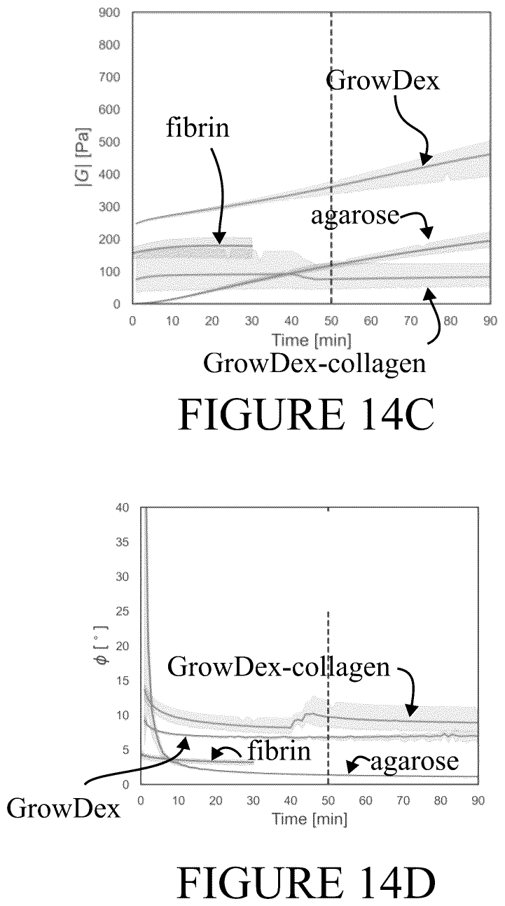

Next, we quantified the heterogeneity of microscale viscoelastic properties inside four different 3D-culture matrix types: agarose, fibrin, GrowDex-collagen, and GrowDex (FIG. 14). These matrices are at the softer range of breast-tumor-related tissue (i.e. the mean |G|≅100-200 Pa). The full summarized mean viscoelasticity values (|G| and φ) of these different matrix types and their concentrations are shown in FIG. 18. Further, supplementary structural heterogeneity information about the used matrix types is available (i.e. agarose, fibrin, and GrowDex).

FIG. 18. Microrheometry for the viscoelasticity of the matrix types.

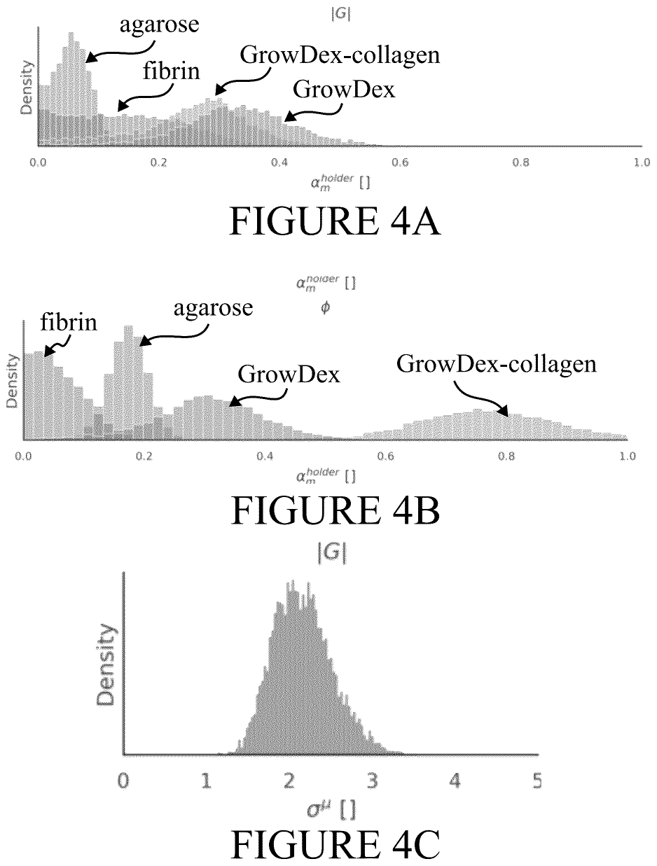

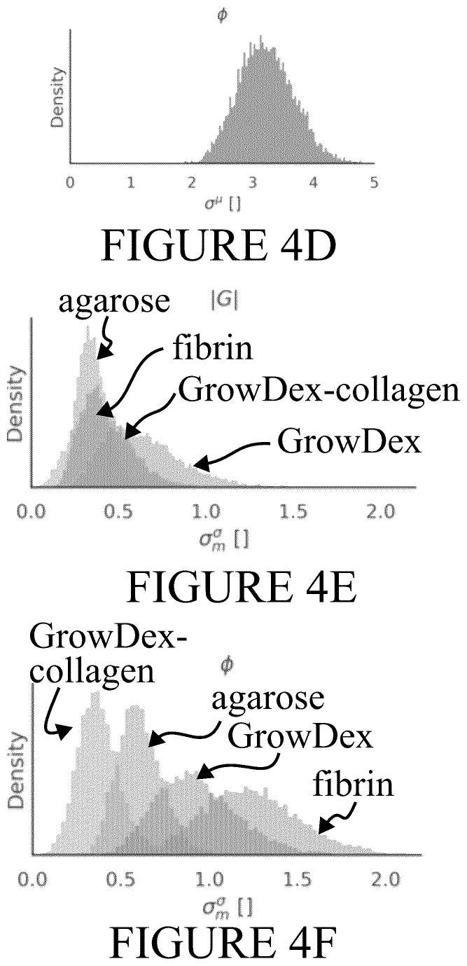

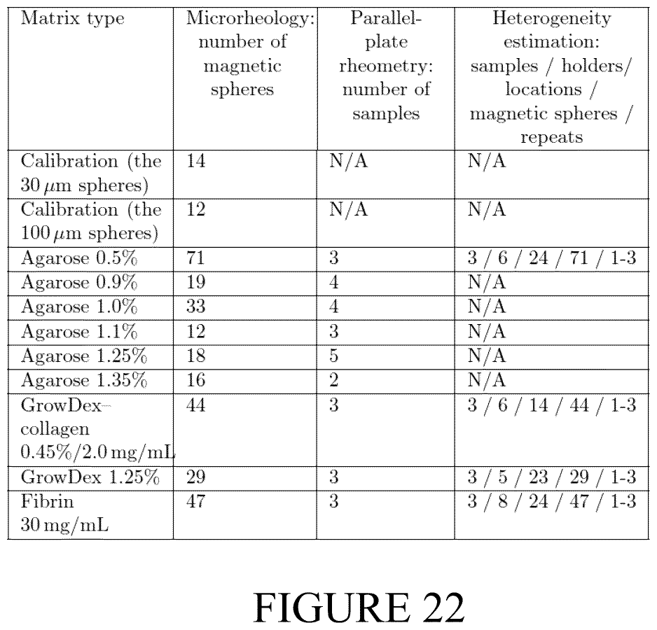

We used the Bayesian multilevel model to quantify the heterogeneity of the absolute shear modulus ((G|) and the phase angle (φ) within each matrix type (FIGS. 4A & 4B). We report the posterior distributions of the heterogeneity parameter (αₘ^{holder}), indicating the spatial variability, for the viscoelastic properties (|G| and φ). The peak value and the width of the distributions describe the magnitude and uncertainty of the heterogeneity in the viscoelastic properties, respectively. The number of samples, sample holders and imaged locations that have passed the data post-processing pipeline are summarized in FIG. 22.

FIG. 4. Multilevel Bayesian model enables distinguishing of the heterogeneity in matrix viscoelasticity from the effects of experimental design and measurement errors. FIG. 4A-4B: Posterior distributions of absolute shear modulus (|G|) and phase angle (φ). For each matrix type, the distribution peak describes the mean of the heterogeneity estimate, while the distribution width indicates uncertainty. FIG. 4C-4D: Estimated average measurement errors are shown for |G| and φ. FIG. 4E-4F: Estimated error's variability between individual magnetic spheres are shown for |G| and φ. The distribution peak describes the magnitude of the estimated error's variability in each matrix type. For all plots, the X axes show the |G| data or the φ data that are z-score normalized (unitless), and the Y axes represent the probability density of the distributions (unitless).

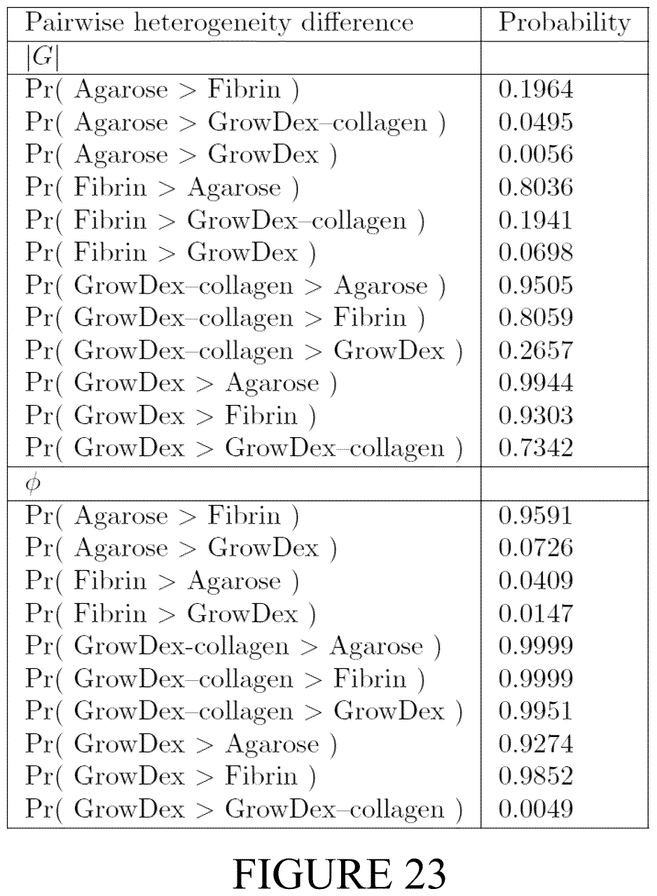

Concerning the absolute shear modulus (i.e. stiffness), agarose and GrowDex are the least and the most heterogeneous matrices based on the model (FIG. 4A). The differences between fibrin, GrowDex and GrowDex-collagen remain uncertain. Regarding the phase angle, fibrin is the least heterogeneous and the heterogeneity increases in the following order: agarose, GrowDex and GrowDex-collagen (FIG. 4B). Pairwise heterogeneity differences are further compared using probability values for absolute shear modulus and phase angle (FIG. 23).

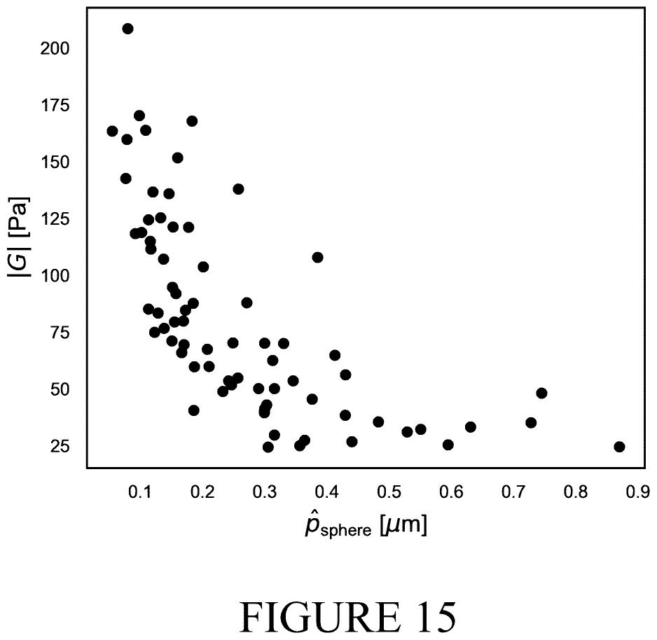

Besides heterogeneity quantification, the model estimates the measurement error and the estimated error variation across the magnetic spheres used within each matrix type. The distribution in FIGS. 4C & 4D estimates the average measurement errors and FIGS. 4E&4F show the variation of the estimated errors. This measurement-error estimation accounts for the fore-mentioned factors, as well as the uncertainty due to the relation between absolute shear modulus and displacement signal amplitude (FIG. 15).

Besides heterogeneity quantification, the model estimates the measurement error and the estimated error variation across the magnetic spheres used within each matrix type. The distribution in FIGS. 4C & 4D estimates the average measurement errors and FIGS. 4E & 4F show the variation of the estimated errors. This measurement-error estimation accounts for the fore-mentioned factors, as well as the uncertainty due to the relation between absolute shear modulus and displacement signal amplitude (FIG. 15).

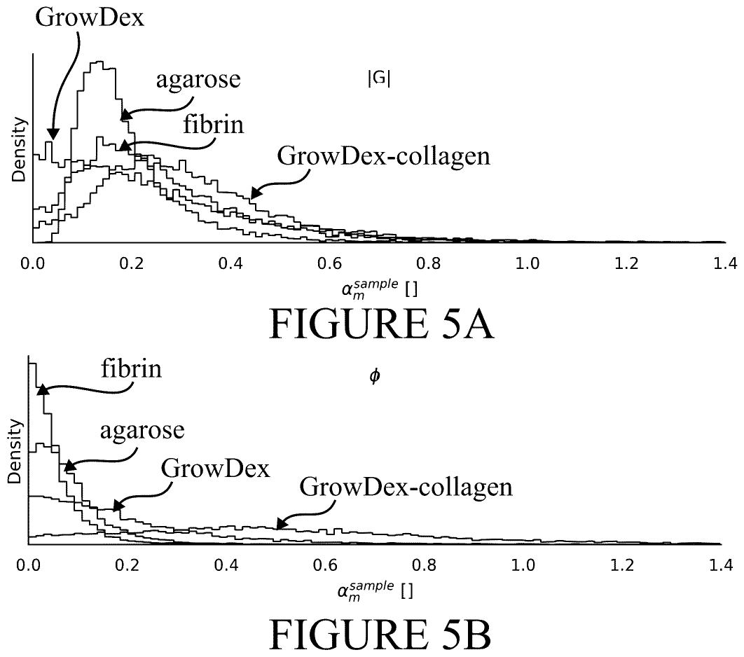

To compare the correspondence between microrheometry and parallel-plate rheometry, we also quantified sample-to-sample variation for each of the matrix types. The microrheometry results using the Bayesian model are summarized in FIG. 5, and the results from the parallel-plate experiments are shown in FIG. 19. The results suggest that both microrheometry and parallel-plate rheometry have the same order of increasing sample-to-sample variation for the matrix types, in respect to shear modulus (|G|). Correspondingly, the results are similar for phase angle (φ), except for fibrin, which has the smallest sample-to-sample variation in microrheology and the third smallest value (or the second highest value) in parallel-plate rheometry. FIG. 5 shows the distributions behind the microrheometry results that have a high degree of overlap indicating uncertainty.

FIG. 19. Parallel-plate rheometry for comparing sample-to-sample variation. Sample-to-sample variation is quantified based on coefficient of variation that is the ratio between standard deviation (σ) and mean. The coefficients of variation for shear modulus (cᵥ,|G|) and for phase angle (cᵥ,φ) are shown.

FIG. 5. Sample-to-sample variation in microrheology experiments based on the hierarchical Bayesian model. The peak values indicate the level of heterogeneity for shear modulus (|G|) and phase angle (φ). The peak-value results suggest the same order of increasing heterogeneity between matrix types as parallel-plate experiments (FIG. 19), except for the phase-angle result of the fibrin matrix. Uncertainty is indicated by the overlap between the distributions.

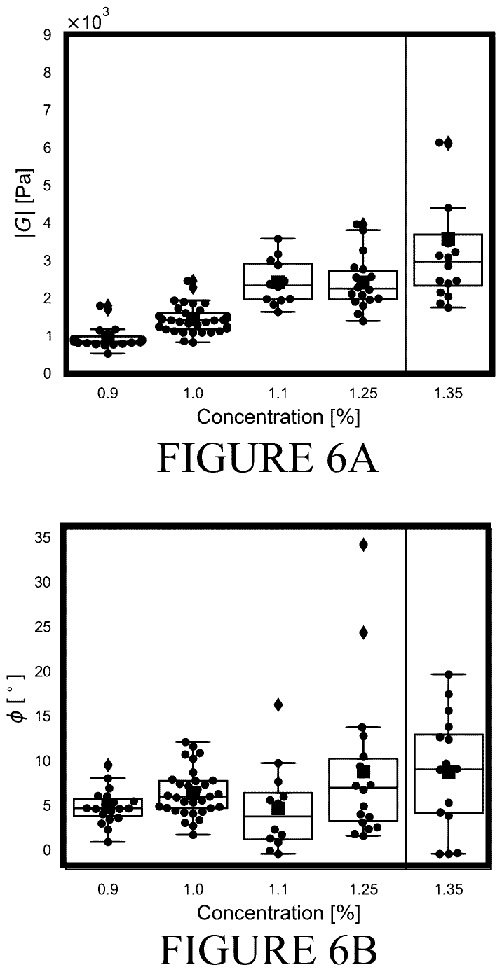

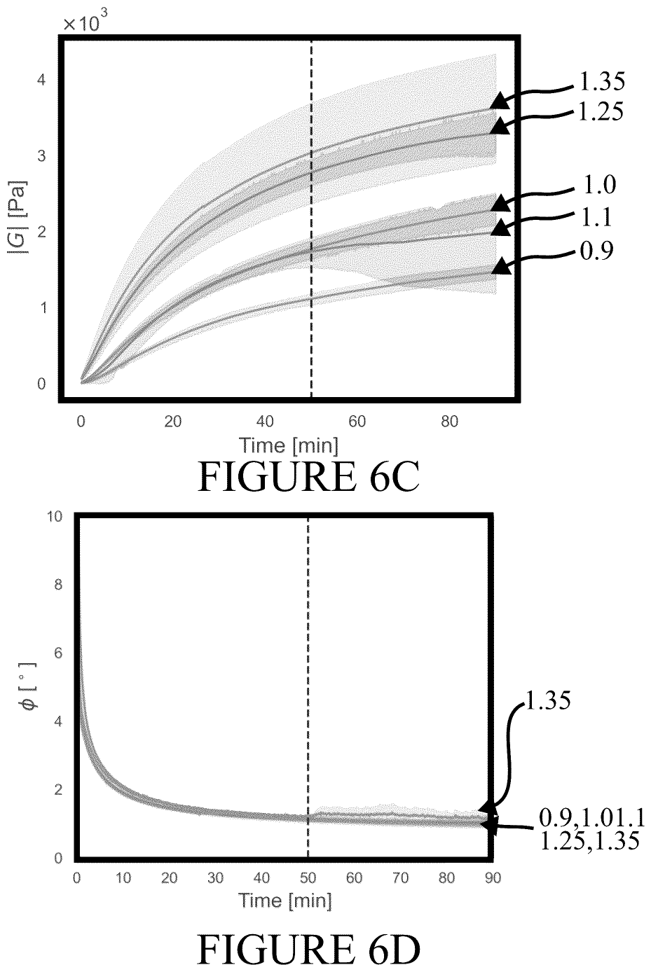

We demonstrate the ability of the microrheometer system to measure microscale viscoelasticity within 3D culture matrices at physiologically relevant stiffness levels (FIGS. 6A & 18). The prepared agarose matrices with concentrations from 0.9% to 1.25% have comparable Young's moduli from 1 kPa to 10 kPa (Eq 5) as in a breast tumor tissue. For the stiffest 1.35% agarose matrices, the analysis pipeline underperformed due a low displacement signal-to-noise ratio. The measurements determined the upper bound of stiffness for the used analysis pipeline and the microrheometer. Further, the phase-angle values of the agarose matrices with the varying concentration are shown in FIGS. 6B & 18. Parallel-plate rheometry is used to confirm the measured absolute shear modulus and phase angle values (FIGS. 6C & 6D). These microrheology measurements that report the microscale values within each sample are well distributed around the average value obtained with the macroscale parallel-plate rheometry, validating the measurements.

FIG. 6. Pointwise microscale viscoelasticity measurements of breast tumor tissue-relevant stiffness levels. FIG. 6A-6B: Absolute shear modulus (|G|) and phase angle (φ) values of agarose matrices with increasing concentration measured using the 100 μm magnetic spheres and the magnetic microrheometer. Agarose matrices with a concentration up to 1.25% can be measured, whereas the signal-to-noise ratio significantly reduces for higher concentrations, including 1.35%, for which measurements are considered unsuccessful. Therefore, the 1.35% agarose condition is separated by a black vertical line from other measurements. The successful microrheometer measurements of |G| for the 1.25% agarose matrix with mean±standard deviation values of 2.41±0.70 kPa correspond to Young's moduli (E) from 6.61±1.93 kPa (v=0.37) to 7.24±2.11 kPa (v=0.50). Multiple individual measurements of |G| exceed 3.5 kPa, denoting 10-11 kPa in Young's modulus (v=0.37-0.50). For both plots, the dark grey spheres show values measured by individual magnetic spheres, while the red squares are the mean values of the spheres. Standardly, the plots' box and whiskers indicate the lower/upper extremes, the 25% and the 75% percentiles, and the median. FIG. 6C-6D: Absolute shear modulus (|G|) and phase angle (φ) values of the agarose matrices at the used concentrations were validated using parallel-plate rheology. The dashed vertical line corresponds to a timepoint of 50 min after the start of the measurements, relevant to microrheological measurements. The curves with darker colors indicate the mean values of the data for each agarose concentration, while the lighter shaded-color regions indicate the lower 5% and the upper 95% percentiles for the data.

We have advanced methods to quantify microscale differences in viscoelasticity within 3D culture matrices that have a stiffness (E) range relevant to breast-tumor tissue, from 100 Pa to 10 kPa. We specifically report on three pertinent areas: the microrheometer's calibration/uncertainty, heterogeneity within different matrix types, and pointwise measurements at breast-tumor relevant stiffness levels.

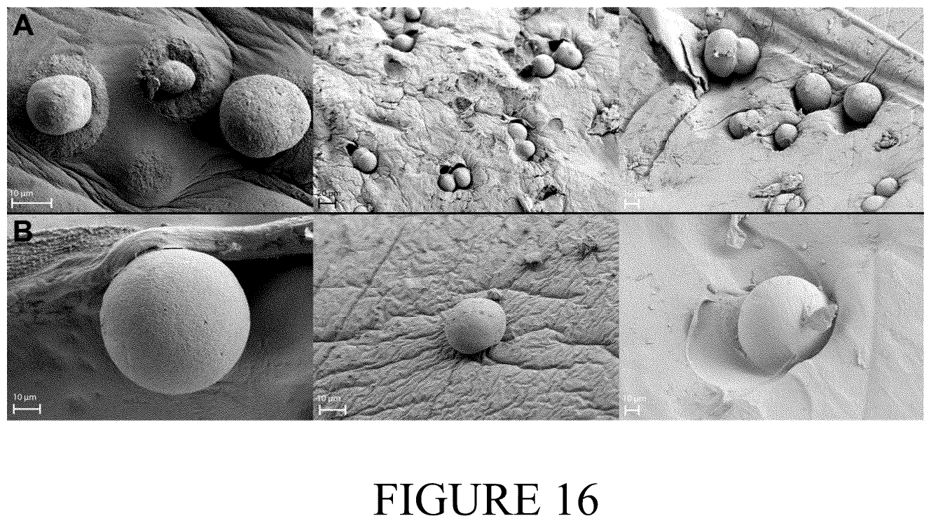

We provide a microrheometer calibration procedure that is independent from the 3D culture matrix type. The calibration enables comparisons between the matrix types, since the calibration coefficients are independent of material properties. Moreover, the microrheometer neither requires any further location-specific calibration before each measurement, nor is limited to the vicinity of the sample surface. Forces exerted on the magnetic spheres are symmetric in the working space between the electromagnets. Further, the following factors impact the results uncertainty. We observed that the silicone oil-based calibration involved no disturbing local flows generated by the forces exerted on the 30 μm magnetic spheres. Yet, the 100 μm magnetic spheres experienced local flows that provided dragging of some reference spheres. Despite of this, the calibration using the 100 μm magnetic spheres provides microrheometry results that are consistent with macroscale parallel-plate rheometry. Further, as theoretically expected in Eq. 4, the absolute shear modulus has a squared dependence on the magnetic sphere diameter. Therefore, the diameter estimation is crucial for accurate results. Further, it is unfeasible to exclude all the spheres with morphological defects from the analysis, because brightfield microscopy provides 2D projection of the spheres. The SEM images reveal that a portion of spheres posses deviation from sphericity and this deviation is a key error source in the experiments (FIG. 16). Additionally, the choice of the magnetic-sphere coating is important, since magnetic spheres have distinct chemicophysical interactions with the matrix material which depend on the matrix type and coating of the magnetic spheres. The smaller 30 μm magnetic spheres, with an appropriate coating for each matrix type, provide a sufficient sphere density within the microscope's field of view for the heterogeneity quantification. Further, we observed a discrepancy of volumetric-force constants between the 30 and 100 μm magnetic spheres at i_{grad}=1.25A (FIG. 17). Based on the datasheet, they are made of the same material. The 25% difference in volumetric force could be due to a deviation of magnetic-material densities between these sphere types.

A heterogeneity quantification approach to estimate microscale spatial differences in viscoelasticity inside each 3D culture matrix type has been developed. Quantifying the viscoelastic cues is crucial to deepen the understanding of individual cell behavior and its relation to matrix viscoelasticity. We used the Bayesian multilevel model to provide an interpretable heterogeneity quantification of the viscoelastic properties within four matrix types. Based on the model, the agarose matrices are the least heterogeneous in stiffness (|G|) compared to the GrowDex, GrowDex-collagen and fibrin matrices. Particularly, the specific order of the latter three matrices is uncertain, suggesting similarity of heterogeneity in stiffness. Further, the degree of heterogeneity for the phase-angle results differed to the ones for the stiffness results. The heterogeneity in phase angle increases in the following order: fibrin, agarose, GrowDex, and GrowDex-collagen. These quantifications report on the heterogeneity differences between the matrix types that have variation in stiffness, thus, the quantifications are unintended to account for stiffness-related heterogeneity differences. The amount of data for each matrix type is expected to impact the heterogeneity uncertainty, observed as the distribution width (FIGS. 4A & 4B). For example, the agarose matrices with the largest dataset (FIG. 22) have the least uncertainty based on the narrowest distributions. Further, the model enables us to assess further the uncertainty in the estimated heterogeneity due to the microrheometer-based measurements. The estimated measurement errors on average are consistent between the different matrix types (FIGS. 4C & 4D). The model quantifies and accounts for the variation of the estimated errors between the individual magnetic probes, specific to each matrix type (FIGS. 4E & 4F). Further, the quantified displacements of magnetic spheres decrease for increased microscale stiffness, which reduces the displacement signal-to-noise ratio, enlarging the uncertainty of the estimated heterogeneity. Therefore, the width of the distributions is expected to increase for the stiffer matrix types (e.g. GrowDex) (FIGS. 4A & 4B). Unexpectedly, the estimates of the measurement error in stiffness are highly overlapping between matrix types indicating consistency of errors regardless of the matrix type (FIG. 4E), and also the distribution widths are mainly similar (FIG. 4A). Expectedly, the estimated error variability in phase angle is higher for the stiffest matrix type (GrowDex) and differs between the matrix types (FIG. 4F), having variable distributions widths (FIG. 4B).

While the direct comparison of the heterogeneity results by the microrheometry with parallel-plate rheometry is unfeasible, these microrheometry results can be indirectly compared to parallel-plate rheometry via the underlying sample-to-sample variation. For shear modulus, the order of increasing sample-to-sample variation of the matrix types is the same between these techniques (FIG. 5). For phase angle, the order of the sample-to-sample variation is also the same, expect for fibrin matrix, having a large overlap of the distribution with other matrices, indicating an elevated uncertainty. These findings suggests consistency between the techniques, although all the distributions behind the microrheometry results have significant overlap related to uncertainty (FIG. 5).

Pointwise measurements at stiffer breast tumor-tissue relevant stiffness levels were carried out. For the purpose, we replaced the 30 μm magnetic spheres, probing softer matrices, with the larger 100 μm magnetic spheres that provide sufficient magnetic forces for probing stiffer matrices. Since these larger magnetic spheres enable measuring only one sphere within the microscope's field of view, less heterogeneity data can be collected at the larger size scales. Therefore, we present pointwise microscale measurements without quantification of heterogeneity. Specifically, the highest measured stiffness levels up to E=10 kPa are shown for 1.25% solid-content 3D agarose matrices, yet, matrices with a higher solid content and higher stiffness levels were unused in the analysis pipeline due to a decreased displacement signal-to-noise ratio.

To summarize, we use magnetic microrheology for the first time to quantify microscale viscoelasticity of several 3D culture matrices and stiffness levels, which are relevant to breast-tumor tissue. Specifically, the measurements stiffness (E) levels between 100 Pa and 10 kPa cover the most of breast tumor-stiffness range. Several aspects have been advanced in relation to the previously developed microrheology technique, including the microrheometer calibration, heterogeneity quantification, and the pointwise microscale measurements up to Young's moduli of 10 kPa. Particularly, the heterogeneity quantification using the Bayesian multilevel model contributes to probe-based magnetic rheology by providing insight into different matrix types' heterogeneity, experimental design, and estimation of measurement errors. These advanced microrheology methods pave the way for enhanced use of 3D cell cultures in breast-cancer research.

FIG. 7: Comsol simulation of magnetic-field gradients. FIGS. 7A-7B: Simulation shows the degree of homogeneity for the magnetic-field gradients within the experimental workspace over the duration of the sinusoidal forces exertion (i.e. 20 s). Horizontal red lines indicate the boundaries of the magnetic hotspot, which is the experimental workspace. The simulation is based on [1] and uses rotational symmetry in cylindrical coordinates.

Materials and methods: data-processing pipeline. To measure microscale viscoelasticity, videos on magnetic and reference sphere displacements are captured. The videos needs to be transformed into the viscoelasticity data. The data-processing pipeline for the purpose is written in Python and operates mostly automatically. Still, user inputs are always required in the step 1 and in the steps 3-4 if the quality of the data is lower. The pipeline works as follows:
1. Magnetic sphere tracking, consisting of automatic tracking with manual initialization.
   (a) Manually initialize bounding boxes for magnetic and reference spheres
   (b) Tracker binarizes the bounding boxes with Otsu-Binarization
   (c) Tracker finds the biggest “blob” for each bounding box and computes the center point
   (d) The bounding box is centered based on the computed new center point
   (e) Repeat (b-d) over the entire video
2. Track rack association, involving with matching the IDs over repeated measurements. The same magnetic sphere should have the same ID over the repeats. This step is only necessary if the spheres are not tracked in the same order over the repeats (i.e bounding boxes are not drawn in the same order for each repeat).
   (a) DBSCAN is used to cluster tracked the xy-coordinates
   (b) New IDs for each magnetic sphere based on the cluster assignment
3. Magnetic sphere radius estimation, including an estimate of the magnetic sphere radius.
   (a) The first repeat of a measurement set should have a sweep video through the z-stack
   (b) Estimate the optimal binarization over the video
   (c) Binarize
   (d) Find the best focus by calculating the Laplacian of a bounding box and calculating the variance (for each magnetic sphere separately). The best focus should have the highest variance.
   (e) Estimate the radius by matching the smallest bounding circle over the magnetic sphere at the best focus point
   (f) Estimate manually if not satisfactory
4. Synchronize current output with the sphere displacement. The current input and the video recorder are started separately from different computers so there is an offset.
   (a) Match the synchronization peaks by calculating the cross correlation and finding the maximum.
   (b) If fails, synchronize manually
5. Find the viscoelastic properties from the displacement information
   (a) Subtract reference sphere signal from the magnetic sphere signals
   (b) Fit sinusoidal curve (scipy's dogbox algorithm)
   (c) Filter out poor signals
      i. If reference sphere is too far or right next to the magnetic sphere (i.e. we define that the distance range between a magnetic and a reference sphere is from 50 μm to 250 μm)
      ii. If amplitude is zero
      iii. If the shape of the sinusoidal signal is not symmetric enough (i.e. detrended displacement signal should have similar area for the two half periods)

Materials and methods: the

$$\frac{\vert {G}_{100} \vert}{\vert {G}_{30} \vert}$$

ratio. By using the given formula for absolute shear modulus (|G|) in Eq. 4, we can derive an approximation for the

$$\frac{\vert {G}_{100} \vert}{\vert {G}_{30} \vert}$$

ratio, as followed:

$$\vert G \vert = \frac{{\hat{F}}_{volumetric} {V}_{sphere}}{3 π {D}_{sphere} {\hat{p}}_{sphere}} , where {V}_{sphere} = \frac{4}{3} {π ( {D}_{sphere} )}^{3}$$

$$\vert G \vert = \frac{{\hat{F}}_{volumetric} \frac{4}{3} {π ( {D}_{sphere} )}^{3}}{3 π {D}_{sphere} {\hat{p}}_{sphere}}$$

$$\vert G \vert = = \frac{{\hat{F}}_{volumetric} \frac{4}{3} {( {D}_{sphere} )}^{2}}{3 {\hat{p}}_{sphere}} = \frac{4}{9} \frac{{{\hat{F}}_{volumetric} ( {D}_{sphere} )}^{2}}{{\hat{p}}_{sphere}}$$

This information is plugged into the calculation of the ratio:

$$\frac{\vert {G}_{100} \vert}{\vert {G}_{30} \vert} = \frac{\frac{{\hat{F}}_{volumetric , 100} \frac{4}{3} {( {D}_{sphere , 100} )}^{2}}{3 {\hat{p}}_{sphere , 100}}}{\frac{{\hat{F}}_{volumetric , 30} \frac{4}{3} {( {D}_{sphere , 30} )}^{2}}{3 {\hat{p}}_{sphere , 30}}}$$

The ratio between the volumetric force constants:

$$\frac{{\hat{F}}_{volumetric , 100}}{{\hat{F}}_{volumetric , 30}} \approx 0.75$$

We want to explore the |G| values at the resolution limit range of the microrheometer: \hat{p}_{sphere,100}≈\hat{p}_{sphere,30}<100 nm

$$\frac{\vert {G}_{100} \vert}{\vert {G}_{30} \vert} = 0.75 \frac{{( {D}_{sphere , 100} )}^{2}}{{( {D}_{sphere , 30} )}^{2}} = 0.75 \frac{{( 100 μ m )}^{2}}{{( 30 μ m )}^{2}}$$

$$\frac{\vert {G}_{100} \vert}{\vert {G}_{30} \vert} = 0.75 \frac{{( 100 μ m )}^{2}}{{( 30 μ m )}^{2}} = 8.367 \approx 8$$

Therefore, we conclude that the 100 μm magnetic spheres are expected to measure approximately 8 times larger stiffness levels than the 30 μm magnetic spheres.

Materials and methods: model comparison. As described in the methods and materials section, the heterogeneity model (Model 1, FIG. 2) was compared against four other variants of the model (Models 2-5, FIGS. 7-10). The results are summarized in FIG. 20, where a higher expected log pointwise predictive density (ELPD) value denotes a better predictive performance. The Model 1 has been chosen as the primary model due to its ability to capture interpretable experimental design and has the second highest ELPD for |G| estimation. The Model 2 has the highest ELDP, which is however within the standard errors for the Models 1-2, and the heterogeneity quantification by the Model 2 is uninterpretable as described in Materials and Methods. The choice of the Models 1-2 for estimating |G| has a slight improving impact on the model performance based on the ELPD, while the most impacting aspect on the performance is to have a unique noise for each magnetic sphere. The unique noise term is needed, because particle tracking and radius estimation are done separately for each magnetic sphere producing different levels of noise. For estimating o, adding hierarchy to the model has no noticeable effect on the performance based on this ELPD analysis (i.e. Model 1 has the lowest ELPD, yet, all the models have a close ELPD that are within standard errors of the Model 3). To summarize, the choice of the Model 1 was mainly done based on the performance to estimate the |G| and the interpretability (i.e. Models 2-5 are partially uninterpretable for the purpose).

FIG. 8: Model 2 definition. The model includes an additional location level effect. The priors are same as in the Model 1.

FIG. 9: Model 3 definition. The model has only a single level of hierarchy.

FIG. 10: Model 4 definition. Only a single parameter for each matrix type material defines the viscoelastic property for a single magnetic sphere.

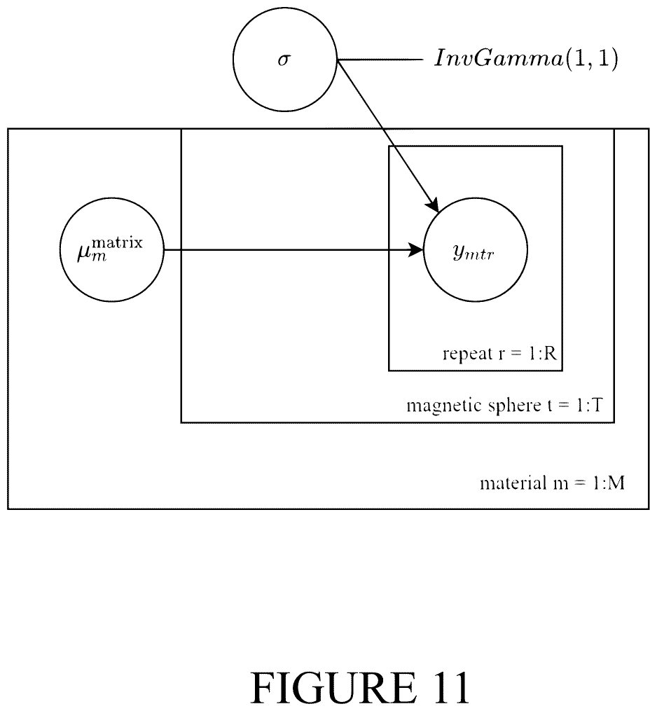

FIG. 11: Model 5 definition. Only a single parameter for each matrix type material defines the viscoelastic property and the measurement noise for a single magnetic sphere.

FIG. 20: Model comparisons based on ELPD and standard error. A higher ELPD value indicates better model performance. The choice of the model is considered more important for estimating |G|. Relatively little gain is achieved between the models when estimating Q.

FIG. 12: Parallel-plate rheometry of viscoelastic properties of 3D-culture matrices with the spheres, and without the spheres. A-B: No significant differences in shear modulus ((G|) and phase angle (φ) are found between the matrices without the spheres, and with the magnetic/reference spheres. The data is for agarose matrices (a 0.9% concentration) and GrowDex matrices (a 1.25% concentration). Comparable viscoelasticity measurements have been previously established for accurate, cell-scale bulk properties of collagen matrices. Because magnetic spheres can measure both the GrowDex and collagen matrices properties, it is reasonable to assume that GrowDex-collagen matrices are similarly measurable.

Materials and methods: calibration. For calibration, the initial estimation method is based on calculating the volumetric force constant as a mean value of each individual magnetic sphere's volumetric force, showing a method-related scatter of individual sphere results (FIG. 21). Here, instead, we use a more accurate, enhanced estimation method. Our approach is directly based on the definition of the force from Stokes' law and a linear regression model (Eq. 6-9). The data in FIG. 21 follows the linear model, as expected, and the Bayesian R² (goodness of fit) is reasonable for all cases. Notably, the R² values are 0.88 for the 30 μm spheres (i_{grad}=1.25 A) and 0.82 for the 100 μm spheres (i_{grad}=1.25 A). NB: we use the current (i_{grad}=1.25 A) for all further experiments and analyses. Based on the low errors shown in FIG. 21, this enhanced estimation improves reliability.

FIG. 21: Comparison of the enhanced (enh.) and initial (init.) estimates of \hat{F}_{volumetric} for the 30 μm and the 100 μm spheres. The error is the percentual ratio between standard deviation and mean.

FIG. 13: Graph of calibration values based on the initial and enhanced estimates of \hat{F}_{volumetric}. The graph compares the \hat{F}_{volumetric} constants by the initial estimate (calculated separately for each sphere) and the enhanced estimate (calculated using Stokes' law). Both of the estimates provide similar mean values. Importantly, the graph illustrates how the enhanced estimate has consistently lower uncertainty than the initial estimate. The estimates show that the \hat{F}_{volumetric} values are increasing linearly as a function of the current i_{grad} for the 30 μm spheres. Each dataset is either for the 30 μm or the 100 μm spheres.

FIG. 22: Number of datapoints from all experiments that have passed the post-processing analysis pipeline.

Results: heterogeneity

FIG. 23: Pairwise comparisons of the heterogeneity in viscoelasticity for the different matrix types. Posterior distributions of αholder m have been compared to provide a probability value quantifying pairwise differences. Only non-zero probabilities are reported.

FIG. 14: Viscoelasticity of the matrix types based on microrheometry and parallel-plate rheometry. FIG. 14A-14B: Absolute shear modulus (|G|) and phase angle (φ) results of the microrheometry measurements for the used matrices types are shown. The compositions of the matrices are as followed: GrowDex has a concentration of 1.25%; GrowDex-collagen has a GrowDex's concentration of 0.45% and a collagen concentration of 2.0 mg/mL; fibrin has a concentration of 30 mg/mL; and agarose has a concentration of 0.5%. For both plots, the dark grey spheres show values measured by individual magnetic spheres, while the red squares are the mean values of the spheres. Standardly, the plots' box and whiskers indicate the lower/upper extremes, the 25% and the 75% percentiles, and the median. FIG. 14C-14D: Absolute shear modulus (|G|) and phase angle (φ) results of the parallel-plate rheometry measurements for the used matrices types are shown. Black vertical dashed line indicates the timepoint when the microrheological measurements have been started for all matrix types apart from the fibrin matrix. Fibrin-matrix measurements were started after 30 min. The curves with darker colors indicate the mean values of the data, while the lighter shaded-color regions indicate the lower 5% and the upper 95% percentiles for the data.

FIG. 15: Absolute shear modulus in relation to the displacement signal amplitude. Absolute shear modulus (|G|) has a multiplicative inverse dependence on the amplitude of the displacement signal (\hat{p}ₛₚₕₑᵣₑ). An increased uncertainty of |G| at low displacement amplitude values is shown (i.e. smaller differences in the displacement amplitude cause larger differences in |G| at lower displacement amplitudes compared to larger displacement amplitudes).

FIG. 16: SEM micrographs of agarose matrices with the 30 μm and the 100 μm spheres. SEM micrographs illustrate the occasional deviation of (A:) the 30 μm and (B:) the 100 μm magnetic spheres from a perfect spherical shape, which is expected to be an error source in our microrheometry methods and detectable in the calibration.

### INDUSTRIAL APPLICABILITY

At least some embodiments of the present invention may find industrial application in characterization of 3D cell cultures, in particular viscoelastic properties, using rheometry and microrheometry.

### ACRONYMS LIST

3D three-dimensional
2D two-dimensional
E Young's modulus
ELPD expected log pointwise predictive density
enh. enhanced
G shear modulus
   |G| absolute shear modulus
init. Initial
MCMC Markov chain Monte Carlo algorithm
SEM scanning electron microscope/scanning electron microscopy

### CITATION LIST

1. Van Helvert S, Storm C, Friedl P. Mechanoreciprocity in cell migration. Nature cell biology. 2018; 20 (1): 8-20.
33. Pokki J, Zisi I, Schulman E, Indana D, Chaudhuri O. Magnetic probe-based microrheology reveals local softening and stiffening of 3D collagen matrices by fibroblasts. Biomedical microdevices. 2021; 23 (2): 1-14.
45. Pokki J, Parmar J, Ergeneman O, Torun H, Guerrero M, Pellicer E, et al. Mobility-enhancing coatings for vitreoretinal surgical devices: hydrophilic and enzymatic coatings investigated by microrheology. ACS Applied Materials & Interfaces. 2015; 7 (39): 22018-22028.
46. Granum P, Madsen M L, McKenna J T K, Hodgkinson D L, Fajans J. Efficient calculations of magnetic fields of solenoids for simulations. Nuclear Instruments and Methods in Physics Research Section A: Accelerators, Spectrometers, Detectors and Associated Equipment. 2022; 1034:166706.
Ossi Arasalo, Magnetic microrheology, The Open Science Framework public repository https://osf.io/jsxqh/(DOI: 10.17605/OSF.IO/JSXQH)
O. Arasalo and A. J. Lehtonen et al. PLOS One (2023) (accepted) (DOI: 10.1371/journal.pone.0282511).

1. A magnetic microrheometry method for estimating microscale microscale viscoelasticity, the method comprising:
obtaining a 3D culture matrix comprising magnetic spheres, said magnetic spheres having a sphere diameter (Dₛₚₕₑᵣₑ);
exerting a sinusoidally varying magnetic force (\hat{F}ₛₚₕₑᵣₑ) using a microrheometer thereby causing sinusoidally varying displacement of the magnetic spheres in the 3D culture matrix;
measuring the displacement of said magnetic spheres; and
estimating microscale viscoelasticity heterogeneity within the 3D culture matrix based at least on the exerted magnetic force (\hat{F}ₛₚₕₑᵣₑ) and the measured displacement of said magnetic spheres.

2. The method according to claim 1, wherein the 3D culture matrix comprises agarose, nanofibrillar cellulose, double-network nanofibrillar cellulose collagen or fibrin.

3. The method according to claim 1, wherein the magnetic spheres have a diameter of 30 or 100 micrometres.

4. The method according to claim 1, wherein the microrheometer comprises two electromagnets.

5. The method according to claim 1, wherein the measurement of the displacement is conducted in a linear viscoelasticity regime of the 3D culture matrix.

6. The method according to claim 1, wherein the exerting of the magnetic force comprises:
applying an offset current (i_{offset}) added to a gradient current input (i_{grad}) to a first electromagnet of the microrheometer and applying the offset current (i_{offset}) subtracted with the gradient current input (i_{grad}) to a second electromagnet of the microrheometer, wherein said gradient current input (i_{grad}) is proportional to the exerted magnetic force (\hat{F}ₛₚₕₑᵣₑ) and gradient current input (i_{grad}) and the exerted magnetic force (\hat{F}ₛₚₕₑᵣₑ) have a phase angle (φ).

7. The method according to claim 6, wherein said gradient current input (i_{grad}) is varied as a function of time with a frequency of 0.05 Hz.

8. The method according to claim 6, wherein the offset current (i_{offset}) is 0.75 A and amplitude of the gradient input current (i_{grad}) is 1.25 A, or 1.00 A, or 0.65 A, amperes.

9. The method according to claim 6, wherein the 3D culture matrix further comprises non-magnetic reference spheres and the measuring further comprises:
capturing video of displacement of the magnetic spheres and the non-magnetic reference spheres, wherein the captured video comprises frames;
tracking the magnetic spheres and the non-magnetic reference spheres in each frame of the captured video, thereby obtaining displacement of said spheres (p_spheres); and
synchronizing the applied gradient current input (i_{grad}) to the displacement of the magnetic and the reference spheres thereby obtaining displacement information (\hat{p}ₛₚₕₑᵣₑ), and said displacement information (\hat{p}ₛₚₕₑᵣₑ) comprises magnetic sphere signals and reference sphere signals.

10. The method according to claim 9, wherein the synchronizing comprises:
cross-correlating peaks of current gradient input (i_{grad}) and magnetic sphere signals or manually synchronizing said gradient current input and magnetic sphere signals in order to obtain the displacement information (\hat{p}ₛₚₕₑᵣₑ).

11. The method according to claim 9, wherein finding the viscoelasticity heterogeneity comprises:
de-trending the magnetic sphere signals by subtracting synchronized non-magnetic reference sphere signals from the magnetic sphere signals;
fitting sinusoidal curves to the de-trended magnetic sphere signals; and
filtering out poor signals in the de-trended magnetic sphere signals, and said poor signals comprise signals wherein;
a non-magnetic reference sphere distance from a magnetic sphere is less than 50 μm or more than 250 μm,
a signal has zero amplitude, and/or
a sinusoidal curve is substantially asymmetric, such as having substantially dissimilar area between two half-periods.

12. The method according to claim 1, wherein the method further comprises determining absolute shear modulus (|G|) and Young's modulus (E), and estimating the microscale viscoelastic properties further comprises:
estimating absolute shear modulus (|G|) from the displacement information (\hat{p}ₛₚₕₑᵣₑ), exerted magnetic force (\hat{F}ₛₚₕₑᵣₑ) and sphere diameter (Dₛₚₕₑᵣₑ) using formula
$$\vert G \vert = \frac{{\hat{F}}_{sphere}}{3 π {D}_{sphere \hat{p} sphere}} ;$$
and
estimating Young's modulus (E) from the estimated absolute shear modulus (|G|), using the Poisson's ratio (v) for said 3D cell culture matrix and formula E=2 (1+v)|G|.

13. The method according to claim 1, wherein the method further comprises determining absolute shear modulus (|G|) and Young's modulus (E), and determining heterogeneity of the 3D cell culture matrix based on the estimated viscoelasticity using Bayesian multilevel model.

14. The method according to claim 1, wherein the obtained 3D culture matrix has Young's moduli from 0.1 kPa to 10 kPa, kilopascals.

15. The method according to claim 9, wherein the non-magnetic reference spheres have a nominal diameter of 6.0 μm.

16. The method according to claim 15, wherein volume fractions of the magnetic spheres and non-magnetic reference spheres in the 3D culture matrix are 0.06% and 0.03%, respectively.

17. The method according to claim 16, wherein the method comprises performing a measurement set comprising 3 to 5 locations, 1 to 3 repeats per location, and wherein the 3D culture matrix comprises 1 to 3 magnetic spheres per location.

18. The method according to claim 1, wherein the method comprises, prior to the measuring of the displacement of the magnetic spheres:
forming a calibration suspension, comprising calibration magnetic spheres, non-magnetic calibration reference spheres and silicone oil, said silicone oil having known viscous properties;
applying a sinusoidally varying gradient input current (i_{grad}) thereby exerting a sinusoidally varying magnetic force (\hat{F}ₛₚₕₑᵣₑ) on calibration suspension causing thereby a sinusoidally varying displacement of the calibration magnetic spheres;
observing the sinusoidally varying displacement of said calibration magnetic spheres with respect to the non-magnetic calibration reference spheres; and
based on phase angle (φ) of the applied sinusoidally varying gradient current input (i_{grad}) and the observed sinusoidally varying displacement, the observed displacement of the calibration magnetic spheres and the known viscous properties of silicone oil, obtaining a relation of gradient input current (i_{grad}) and the exerted sinusoidally varying magnetic force (\hat{F}ₛₚₕₑᵣₑ) within silicone oil.
